(19) United States
(12) Patent Application Publication
(10) Pub. No.: US 2026/0324106 A1
(43) Pub. Date: Oct. 15, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: TOMOHIKO KAWAMURA, KANAGAWA (JP)

(21) Appl. No.: 19/491,498

(22) PCT Filed: May 13, 2024
(86) PCT No.: PCT/JP2024/017674

§ 371 Date: Dec. 9, 2025

(30) Foreign Application Priority Data
Jun. 28, 2023 (JP) 2023-105944

(51) Int. Cl. H10F 39/00; H10F 30/221; H10F 39/18

(52) U.S. Cl. CPC H10F 39/8023; H10F 30/221; H10F 39/182; H10F 39/8027; H10F 39/8033; H10F 39/80373; H10F 39/807; H10F 39/813; H10F 39/014

(57) ABSTRACT

To increase a degree of freedom in arrangement of elements in a photoelectric conversion region. A photodetection device includes a semiconductor layer including a photoelectric conversion region that has a first surface portion and a second surface portion located opposite to each other in a thickness direction and is partitioned by an isolation region extending in the thickness direction. Then, the photoelectric conversion region includes: an upper surface portion located on the first surface portion side of the semiconductor layer; a side surface portion located on the isolation region side; a pixel transistor provided on the upper surface portion side; a floating diffusion region that is provided on the upper surface portion side and holds a signal charge photoelectrically converted by the photoelectric conversion unit; and a capacitive element connected to the floating diffusion region. Then, the capacitive element includes: a first electrode provided in the isolation region adjacent to the side surface portion of the photoelectric conversion region with a dielectric film interposed therebetween; and a second electrode provided adjacent to the first electrode inside the side surface portion of the photoelectric conversion region.

### TECHNICAL FIELD

The present technology (technology according to the present disclosure) relates to a photodetection device and an electronic apparatus, and particularly relates to a technology effective when applied to a photodetection device having a capacitive element electrically connected to a floating diffusion region and an electronic apparatus using the photodetection device.

### BACKGROUND ART

A photodetection device such as a solid-state imaging device or a side recognition device includes a transfer transistor that transfers photoelectrically converted signal charges to a floating diffusion region, and a readout circuit (pixel circuit) that outputs a pixel signal based on the signal charges accumulated (held) in the floating diffusion region.

Patent Document 1 discloses a solid-state imaging device in which a floating diffusion region, a transfer transistor, a pixel transistor included in a readout circuit, and the like are provided in a photoelectric conversion region of a semiconductor layer. In addition, Patent Document 1 also discloses a photoelectric conversion region partitioned by a trench-type isolation region.

Meanwhile, Patent Document 2 discloses a technique in which a capacitive element electrically connected to a floating diffusion region is provided in a photoelectric conversion region.

### CITATION LIST

### Patent Document

Patent Document 1: Japanese Patent Laid-open Publication No. 2021-101491

Patent Document 2: WO2020/105634

### SUMMARY OF THE INVENTION

### Problems to be Solved by the Invention

Meanwhile, in recent years, high-resolution image sensors have been demanded in the market, and development of image sensors with a reduced pixel size has been advanced.

However, as the pixel size is reduced, the degree of freedom in arrangement of elements such as a transfer transistor, a pixel transistor, and a capacitive element in the photoelectric conversion region is reduced.

An object of the present technology is to provide a technology capable of increasing a degree of freedom in arrangement of elements in a photoelectric conversion region.

### Solutions to Problems

(1) A photodetection device according to an aspect of the present technology includes a semiconductor layer including a photoelectric conversion region that has a first surface portion and a second surface portion located opposite to each other in a thickness direction and is partitioned by an isolation region extending in the thickness direction.

Then, the photoelectric conversion region includes:
an upper surface portion located on the first surface portion side of the semiconductor layer;
a side surface portion located on the isolation region side;
a pixel transistor provided on the upper surface portion side;
a floating diffusion region that is provided on the upper surface portion side and holds a signal charge photoelectrically converted by the photoelectric conversion unit; and
a capacitive element connected to the floating diffusion region.

Then, the capacitive element includes:
a first electrode provided outside the side surface portion of the photoelectric conversion region with a dielectric film interposed therebetween; and
a second electrode provided inside the side surface portion of the photoelectric conversion region so as to be adjacent to the first electrode.

(2) An electronic apparatus according to another aspect of the present technology includes:
the photodetection device;
an optical lens that forms an image of image light from a subject on an imaging surface of the photodetection device; and a signal processing circuit that performs signal processing on a signal output from the photodetection device.

### BRIEF DESCRIPTION OF DRAWINGS

FIG. 1 is a chip layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a readout circuit according to the first embodiment of the present technology.

FIG. 4A is a plan view schematically illustrating a configuration example of four pixels included in a pixel array unit of FIG. 1.

FIG. 4B is an enlarged plan view of a main part of one pixel in FIG. 4A.

FIG. 5A is a longitudinal sectional view schematically illustrating a longitudinal sectional structure taken along line a4-a4 in FIG. 4.

FIG. 5B is a schematic longitudinal sectional view in which a part of FIG. 5A is enlarged.

FIG. 6A is a longitudinal sectional view schematically illustrating a longitudinal sectional structure taken along line b4-b4 in FIG. 4.

FIG. 6B is a schematic longitudinal sectional view in which a part of FIG. 6A is enlarged.

FIG. 7A is a longitudinal sectional view schematically illustrating a step of a method for manufacturing the solid-state imaging device according to the first embodiment of the present technology.

FIG. 7B is a longitudinal sectional view schematically illustrating a step subsequent to FIG. 7A.

FIG. 7C is a longitudinal sectional view schematically illustrating a step subsequent to FIG. 7B.

FIG. 7D is a longitudinal sectional view schematically illustrating a step subsequent to FIG. 7C.

FIG. 7E is a longitudinal sectional view schematically illustrating a step subsequent to FIG. 7D.

FIG. 7F is a longitudinal sectional view schematically illustrating a step subsequent to FIG. 7E.

FIG. 7G is a longitudinal sectional view schematically illustrating a step subsequent to FIG. 7F.

FIG. 8 is a longitudinal sectional view of a main part schematically illustrating Modification 1-1 of the first embodiment.

FIG. 9 is a longitudinal sectional view of a main part schematically illustrating Modification 1-2 of the first embodiment.

FIG. 10 is a plan view schematically illustrating a configuration example of four pixels in a solid-state imaging device according to a second embodiment of the present technology.

FIG. 11 is a longitudinal sectional view schematically illustrating a longitudinal sectional structure taken along line a10-a10 in FIG. 10.

FIG. 12 is a longitudinal sectional view schematically illustrating a longitudinal sectional structure taken along line b10-b10 in FIG. 10.

FIG. 13 is a plan view schematically illustrating a configuration example of four pixels in a solid-state imaging device according to a third embodiment of the present technology.

FIG. 14 is a longitudinal sectional view schematically illustrating a longitudinal sectional structure taken along line a13-a13 in FIG. 13.

FIG. 15 is a longitudinal sectional view schematically illustrating a longitudinal sectional structure taken along line b13-b13 in FIG. 13.

FIG. 16 is an equivalent circuit diagram illustrating a configuration example of a readout circuit in a solid-state imaging device according to a fourth embodiment of the present technology.

FIG. 17 is a plan view schematically illustrating a configuration example of two pixels in the solid-state imaging device according to the fourth embodiment of the present technology.

FIG. 18 is a longitudinal sectional view schematically illustrating a longitudinal sectional structure taken along line a17-a17 in FIG. 17.

FIG. 19 is a diagram illustrating a configuration example of an electronic apparatus according to a fifth embodiment of the present technology.

### MODE FOR CARRYING OUT THE INVENTION

Embodiments of the present technology will be described in detail hereinafter with reference to the drawings.

Note that in the illustration of the drawings referred to in the following description, the same or similar portions are denoted by the same or similar reference signs. It should be noted that the drawings are schematic, and relationships between thicknesses and planar dimensions, ratios of thicknesses between layers, and the like are different from actual ones. Therefore, specific thicknesses and dimensions should be determined in consideration of the following description.

Furthermore, it is needless to say that portions having different dimensional relationships and ratios are included between the drawings. Furthermore, the effects described herein are merely illustrative and not limiting, and there may also be other effects.

Furthermore, the following embodiments illustrate devices and methods for implementing the technical idea of the present technology and are not intended to limit the configuration to those described below. That is, various modifications can be made to the technical idea of the present technology within the technical scope described in the claims.

Furthermore, definitions of directions such as up and down in the following description are merely for convenience of description and are not intended to limit the technical idea of the present technology. For example, it goes without saying that when an object is observed while being rotated by 90°, the up and down are converted into left and right, and when the object is observed while being rotated by 180°, the up and down are inverted.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction.

Then, in the following embodiments, a thickness direction of a Semiconductor layer 21 described later will be described as the Z direction.

### First Embodiment

In a first embodiment, an example where the present technology is applied, as a photodetection device, to a solid-state imaging device that is a back-illuminated complementary metal-oxide-semiconductor (CMOS) image sensor will be described. Furthermore, in the first embodiment, a readout circuit including a capacitive element connected to a floating diffusion region will be described.

### Overall Configuration of Solid-State Imaging Device

First, an overall configuration of a solid-state imaging device 1A will be described.

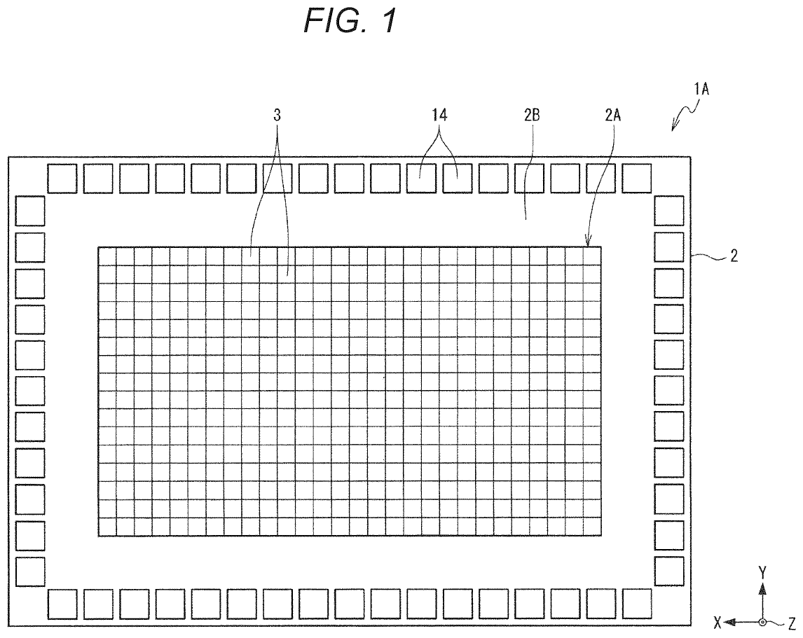

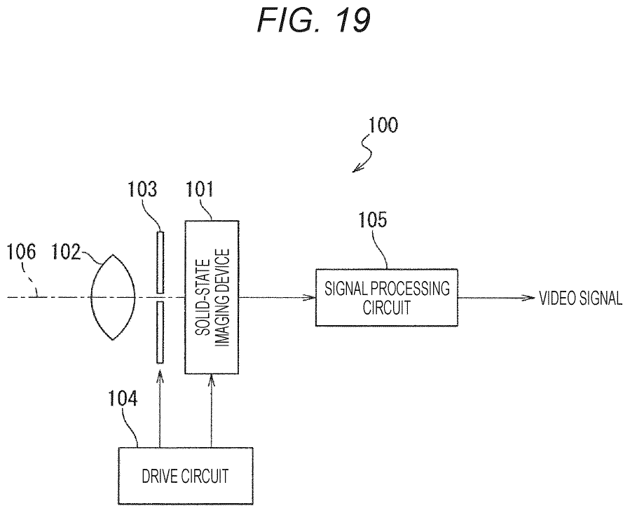

As illustrated in FIG. 1, the solid-state imaging device 1A according to the first embodiment of the present technology mainly includes a semiconductor chip 2 having a square two-dimensional planar shape in plan view. That is, the solid-state imaging device 1A is mounted on the semiconductor chip 2, and the semiconductor chip 2 can be regarded as the solid-state imaging device 1A. As illustrated in FIG. 19, the solid-state imaging device 1A (101) takes in image light (incident light 106) from a subject via an optical lens 102, converts a light amount of the incident light 106 formed on an imaging surface into an electrical signal in units of pixels, and outputs the electrical signal as a pixel signal.

As illustrated in FIG. 1, the semiconductor chip 2 on which the solid-state imaging device 1A is mounted includes, in a two-dimensional plane including the X direction and the Y direction orthogonal to each other, a square pixel array unit 2A provided in a central portion thereof and a peripheral portion 2B provided outside the pixel array unit 2A in such a way as to surround the pixel array unit 2A. A semiconductor wafer including the semiconductor layer 21 described later is diced into small pieces, each serving as a chip formation region, to form the semiconductor chip 2 in a manufacturing process. The configuration of the solid-state imaging device 1A, which will be described below, therefore, is substantially similar to that before the semiconductor wafer is diced into small pieces. That is, the present technology is applicable to both a semiconductor chip and a semiconductor wafer.

The pixel array unit 2A is, for example, a light receiving surface that receives light condensed by the optical lens (optical system) 102 illustrated in FIG. 19. Then, in the pixel array unit 2A, a plurality of pixels 3 (sensor pixels) is arranged in a matrix on a two-dimensional plane including the X direction and the Y direction. In other words, the pixels 3 are repeatedly arranged in the X direction and the Y direction orthogonal to each other in the two-dimensional plane.

As illustrated in FIG. 1, a plurality of bonding pads 14 is arranged in the peripheral portion 2B. Each of the plurality of bonding pads 14 is arranged along each of four sides of the two-dimensional plane of the semiconductor chip 2, for example. Each of the plurality of bonding pads 14 functions as an input/output terminal that electrically connects the semiconductor chip 2 and an external device to each other.

### <Logic Circuit>

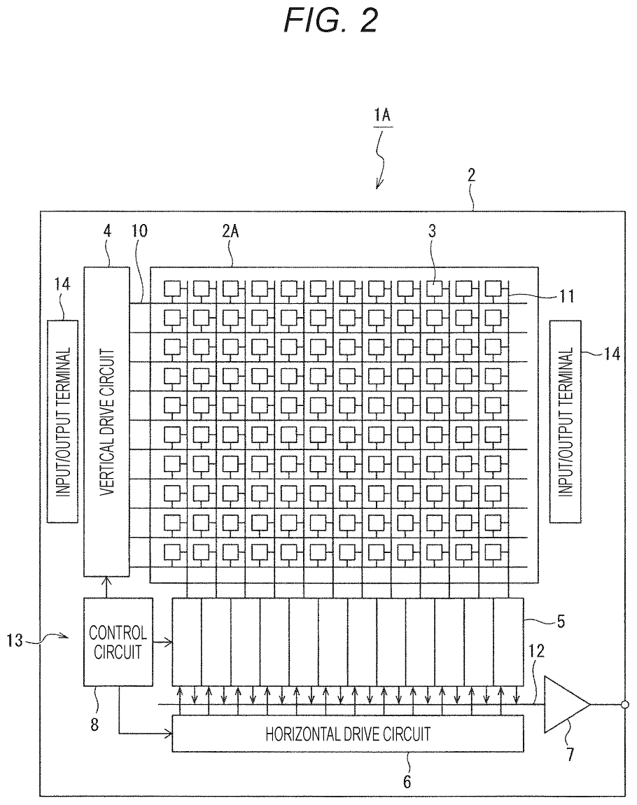

The semiconductor chip 2 includes a logic circuit 13 illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel metal-oxide-semiconductor field-effect transistor (MOSFET) and a p-channel MOSFET as field-effect transistors.

The vertical drive circuit 4 illustrated in FIG. 2 includes a shift register, for example. The vertical drive circuit 4 sequentially selects desired pixel drive lines 10, supplies pulses for driving the pixels 3 to the selected pixel drive lines 10, and drives the pixels 3 row by row. That is, the vertical drive circuit 4 selectively scans the individual pixels 3 in the pixel array unit 2A sequentially in a vertical direction row by row and supplies pixel signals from the pixels 3 based on the signal charge generated by photoelectric conversion units of the pixels 3 in accordance with the amount of light received to the corresponding column signal processing circuits 5 through corresponding vertical signal lines 11.

The column signal processing circuit 5 illustrated in FIG. 2 is arranged, for example, for each column of the pixels 3, and performs signal processing such as noise removal for each pixel column on signals output from the pixels 3 of one row. For example, each column signal processing circuit 5 performs signal processing such as correlated double sampling (CDS) for removing pixel-specific fixed pattern noise, and analog-to-digital (AD) conversion.

The horizontal drive circuit 6 illustrated in FIG. 2 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output pixel signals obtained as a result of signal processing to a horizontal signal line 12.

The output circuit 7 illustrated in FIG. 2 performs signal processing on the pixel signals sequentially supplied from each of the column signal processing circuits 5 through the horizontal signal line 12, and outputs the processed pixel signals. As the signal processing, for example, buffering, black level adjustment, column variation correction, various types of digital signal processing, and the like can be used.

The control circuit 8 illustrated in FIG. 2 generates clock signals and control signals as references for operations of the vertical drive circuit 4, the column signal processing circuits 5, the horizontal drive circuit 6, and the like on the basis of a vertical synchronization signal, a horizontal synchronization signal, and a master clock signal. Then, the control circuit 8 then outputs the generated clock signals and control signals to the vertical drive circuit 4, the column signal processing circuits 5, the horizontal drive circuit 6, and the like.

### <Photoelectric Conversion Circuit and Readout Circuit>

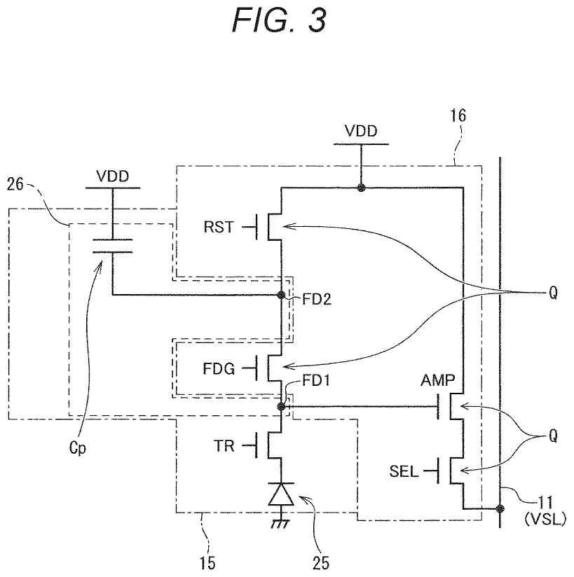

The semiconductor chip 2 includes a photoelectric conversion circuit 15 and a readout circuit (pixel circuit) 16 illustrated in FIG. 3.

The photoelectric conversion circuit 15 includes, but is not limited to, for example, a photoelectric conversion unit 25, a charge holding unit 26 that holds (accumulates) the signal charge photoelectrically converted by the photoelectric conversion unit 25, and a transfer transistor TR that transfers the signal charge photoelectrically converted by the photoelectric conversion unit 25 to the charge holding unit 26. The photoelectric conversion circuit 15 is provided for each pixel 3.

The readout circuit 16 includes, but is not limited to, an amplification transistor AMP, a selection transistor SEL, a reset transistor RST, and a switching transistor FDG, for example, as the pixel transistor Q. That is, the readout circuit 16 of the first embodiment has a four-transistor configuration.

Here, in the first embodiment, as an example, a circuit configuration in which one readout circuit 16 is allocated to each pixel 3 is adopted, but the present invention is not limited to the first embodiment. Furthermore, for example, a circuit configuration may be adopted in which one readout circuit 16 is allocated to two pixels 3 as one unit, or a circuit configuration may be adopted in which one readout circuit 16 is allocated to three or more pixels 3 as one unit.

### <Photoelectric Conversion Circuit>

### (Photoelectric Conversion Unit)

The photoelectric conversion unit 25 illustrated in FIG. 3 includes, for example, a pn junction photodiode (PD), and generates a signal charge in accordance with the amount of received light. Furthermore, the photoelectric conversion unit 25 temporarily holds (accumulates) the generated signal charge.

The photoelectric conversion unit 25 has a cathode side electrically connected to a source region of the transfer transistor TR and an anode side electrically connected to a reference potential line (for example, ground).

### (Transfer Transistor)

The transfer transistor TR illustrated in FIG. 3 transfers the signal charge photoelectrically converted by the photoelectric conversion unit 25 to the charge holding unit 26. In the transfer transistor TR, a source region is electrically connected to the cathode side of the photoelectric conversion unit 25, and a drain region is electrically connected to the charge holding unit 26. Then, a gate electrode of the transfer transistor TR is electrically connected to a transfer transistor drive line among the pixel drive lines 10 illustrated in FIG. 2.

### (Charge Holding Unit)

Although not limited thereto, the charge holding unit 26 includes, for example, two floating diffusion regions FD1 and FD2 and a capacitive element Cp as illustrated in FIG. 3. The floating diffusion region FD1 is connected between the transfer transistor TR and the switching transistor FDG. The floating diffusion region FD2 is connected between the switching transistor FDG and the reset transistor RST. The capacitive element Cp is connected to the floating diffusion region FD2.

The floating diffusion region FD1 temporarily accumulates and holds the signal charge transferred from the photoelectric conversion unit 25 via the transfer transistor TR.

The floating diffusion region FD2 and the capacitive element Cp temporarily accumulate and hold the signal charge transferred from the photoelectric conversion unit 25 via the transfer transistor TR when the switching transistor FDG is in a conductive state (ON state).

### <Readout Circuit>

As illustrated in FIG. 3, an input stage of the readout circuit 16 is electrically connected to the floating diffusion region FD1 of the charge holding unit 26. Then, the readout circuit 16 reads out the signal charges held in the floating diffusion region FD of the charge holding unit 26 when the switching transistor FDG is in a non-conductive state (OFF state), and reads out the signal charges held in the floating diffusion regions FD1 and FD2 of the charge holding unit 26 and the capacitive element Cp when the switching transistor FDG is in a conductive state (ON state). Then, the readout circuit 16 outputs a pixel signal based on the read signal charge. In other words, the readout circuit 16 converts the signal charge photoelectrically converted by the photoelectric conversion unit 25 (photodiode PD) into a pixel signal based on the signal charge and outputs the pixel signal.

The pixel transistor Q (AMP, RST, SEL, FDG) included in the readout circuit 16 and the transfer transistor TR included in the photoelectric conversion circuit 15 are configured as insulated gate field effect transistors, for example, by metal-oxide-semiconductor field-effect transistors (MOSFET) whose gate insulating film is a silicon oxide (SiO₂) film. Furthermore, as the pixel transistor Q and the transfer transistor TR, a metal insulator semiconductor FET (MISFET) in which the gate insulating film includes a silicon nitride (Si₃N₄) film or a laminated film such as a silicon nitride film and a silicon oxide film may be used.

Among the pixel transistors Q (AMP, RST, SEL, FDG) included in the readout circuit 16, the selection transistor SEL, the reset transistor RST, and the switching transistor FDG mainly function as switching elements. Then, the remaining amplification transistor AMP mainly functions as an amplification element.

In the amplification transistor AMP illustrated in FIG. 3, the source region is electrically connected to the drain region of the selection transistor SEL, and the drain region is electrically connected to the power supply line VDD and the drain region of the reset transistor RST. Then, the gate electrode of the amplification transistor AMP is electrically connected to the floating diffusion region FD1 of the charge holding unit 26, the drain region of the transfer transistor TR, and the source region of the switching transistor FDG.

The selection transistor SEL illustrated in FIG. 3 has a source region electrically connected to the vertical signal line 11 (VSL) and a drain region electrically connected to the source region of the amplification transistor AMP. Then, a gate electrode of the selection transistor SEL is electrically connected to a selection transistor drive line among pixel drive lines 10 illustrated in FIG. 2.

In the reset transistor RST illustrated in FIG. 3, the source region is electrically connected to each of the floating diffusion region FD2 of the charge holding unit 26 and the drain region of the switching transistor FDG, and the drain region is electrically connected to each of the power supply line VDD and the drain region of the amplification transistor AMP. Then, a gate electrode of the reset transistor RST is electrically connected to a reset transistor drive line among the pixel drive lines 10 illustrated in FIG. 2.

In the switching transistor FDG illustrated in FIG. 3, the source region is electrically connected to each of the floating diffusion region FD1 of the charge holding unit 26, the drain region of the transfer transistor TR, and the gate electrode of the amplification transistor AMP, and the drain region is electrically connected to each of the floating diffusion region FD2 of the charge holding unit 26 and the drain region of the reset transistor RST. Then, the switching transistor FDG has a gate electrode electrically connected to a switching transistor drive line among the pixel drive lines 10 illustrated in FIG. 2.

When the transfer transistor TR is turned on, the transfer transistor TR illustrated in FIG. 3 transfers the signal charge generated by the photoelectric conversion unit 25 (photodiode PD) to the charge holding unit 26.

When the reset transistor RST is turned on, the reset transistor RST illustrated in FIG. 3 resets the potential (signal charge) of the charge holding unit 26 (FD1, FD2, Cp) to the potential of the power supply line VDD.

The selection transistor SEL illustrated in FIG. 3 controls the output timing of the pixel signal from the readout circuit 16.

The amplification transistor AMP illustrated in FIG. 3 generates a signal of a voltage corresponding to the level of the signal charge held in the charge holding unit 26 as a pixel signal. The amplification transistor AMP constitutes a source follower type amplifier, and outputs a pixel signal having a voltage corresponding to the level of the signal charge generated by the photoelectric conversion unit 25 (photodiode PD). When the selection transistor SEL is turned on, the amplification transistor AMP amplifies the potential of the charge holding unit 26, and outputs a voltage corresponding to the potential to the column signal processing circuit 5 via the vertical signal line 11 (VSL).

The switching transistor FDG illustrated in FIG. 3 controls charge retention by the charge holding unit 26 and adjusts an image magnification of a voltage according to a potential amplified by the amplification transistor AMP.

The switching transistor FDG is used to switch the conversion efficiency. In general, the pixel signal is small at a time of imaging in a dark place. If the FD capacitance C (floating diffusion capacitance C) of the charge holding unit 26 is large at the time of performing charge-voltage conversion on the basis of Q=CV, the voltage V when converted into a voltage by the amplification transistor AMP becomes small. On the other hand, in a bright place, since the pixel signal becomes large, unless the FD capacitance C of the charge holding unit 26 is large, the charge holding unit 26 cannot receive the charge of the photoelectric conversion unit 25 (photodiode PD). Furthermore, the FD capacitance C of the charge holding unit 26 needs to be large so that the voltage V when converted into the voltage by the amplification transistor AMP does not become too large (in other words, it is made smaller). In view of these, when the switching transistor FDG is turned on, the gate capacitance of the switching transistor FDG increases, so that the entire FD capacitance C increases. On the other hand, when the switching transistor FDG is turned off, the entire FD capacitance C decreases. In this manner, by switching on/off of the switching transistor FDG, the FD capacitance C can be made variable, and the conversion efficiency can be switched.

During operation of the solid-state imaging device 1A according to the first embodiment, signal charges generated in the photoelectric conversion unit 25 of the pixel 3 are held (accumulated) in the charge holding unit 26 via the transfer transistor TR of the pixel 3. Then, the signal charge held in the charge holding unit 26 is read by the readout circuit 16 and applied to the gate electrode of the amplification transistor AMP of the readout circuit 16. A horizontal line selection control signal is provided from the vertical shift register to the gate electrode of the selection transistor SEL of the readout circuit 16. Then, setting the selection control signal to a high (H) level then brings the selection transistor SEL into conduction to allow a current corresponding to the potential of the floating diffusion region FD amplified by the amplification transistor AMP to flow to the vertical signal line 11. Furthermore, by setting the reset control signal applied to the gate electrode of the reset transistor RST of the readout circuit 16 to the high (H) level, the reset transistor RST is conducted, and the signal charge accumulated in the floating diffusion region FD is reset.

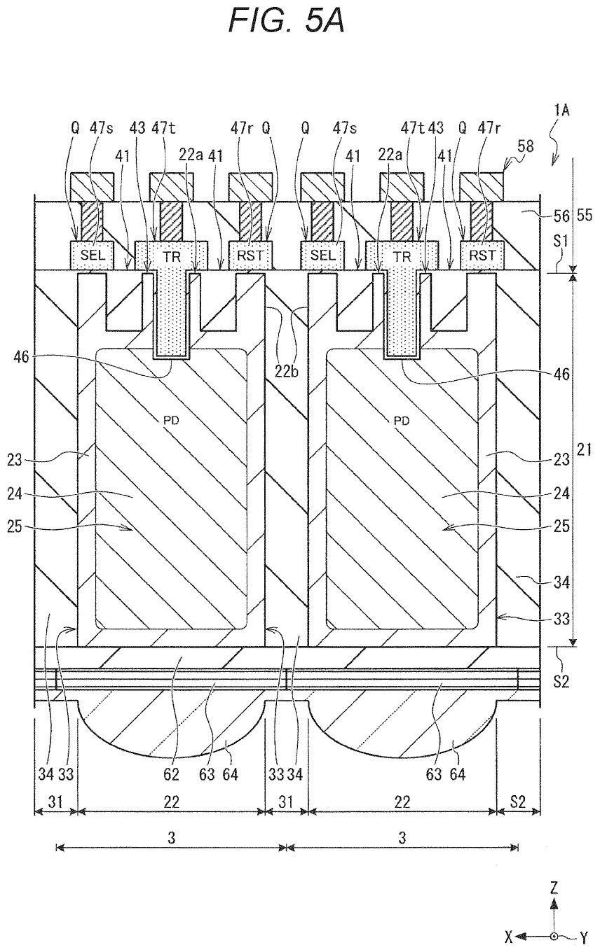

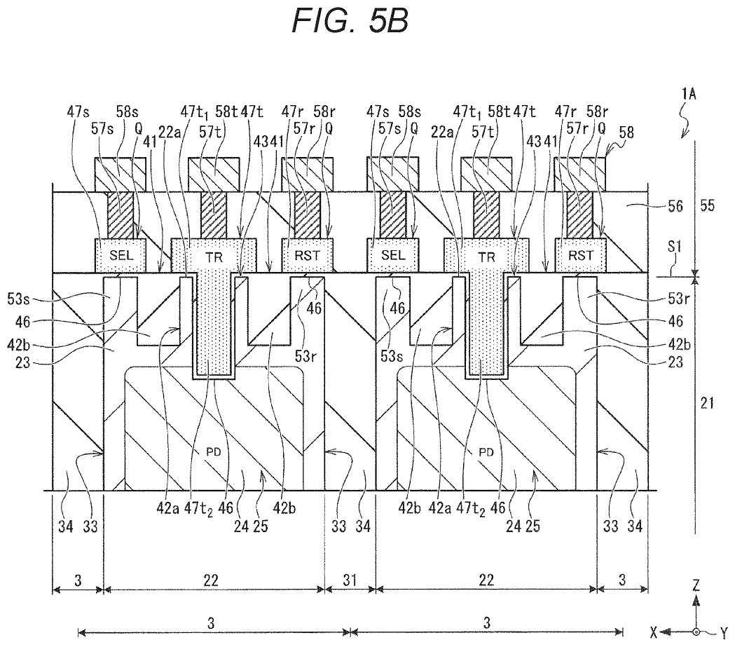

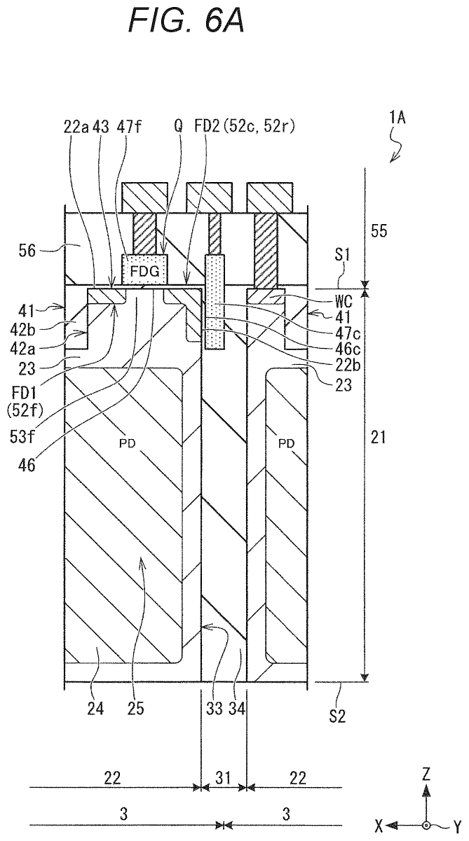

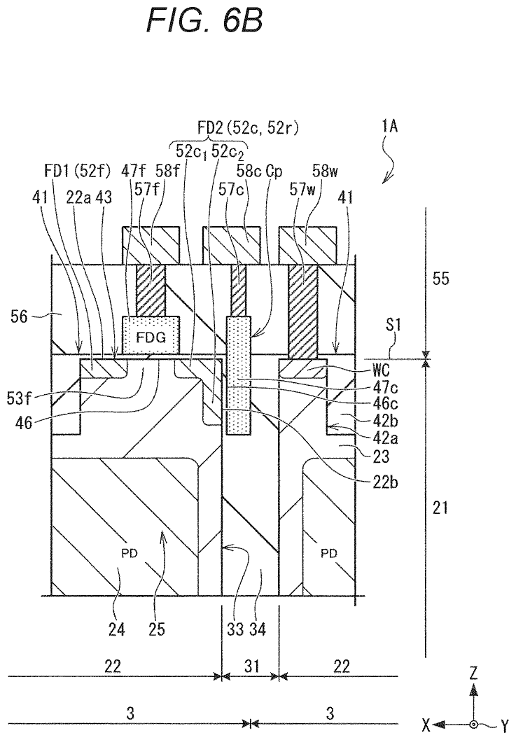

Each of the photoelectric conversion unit 25, the transfer transistor TR, the floating diffusion regions FD1 and FD2, and the capacitive element Cp illustrated in FIG. 3 is mounted on the semiconductor layer 21 (see FIGS. 5A and 6A) to be described later. Furthermore, although not limited thereto, the pixel transistor Q (AMP, RST, SEL) included in the readout circuit 16 in FIG. 3 is also mounted on the semiconductor layer 21, for example.

### <<Specific Configuration of Solid-State Imaging Device>>

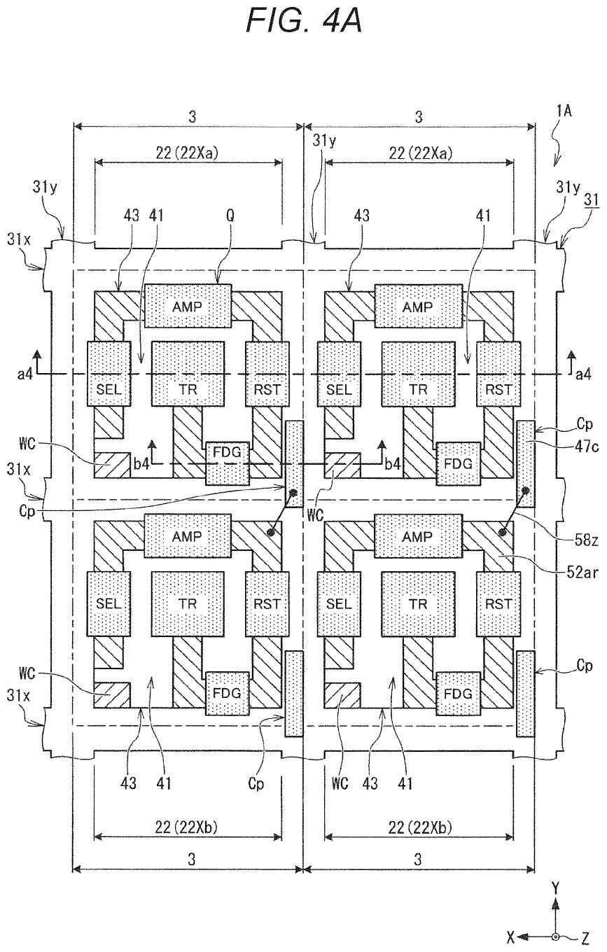

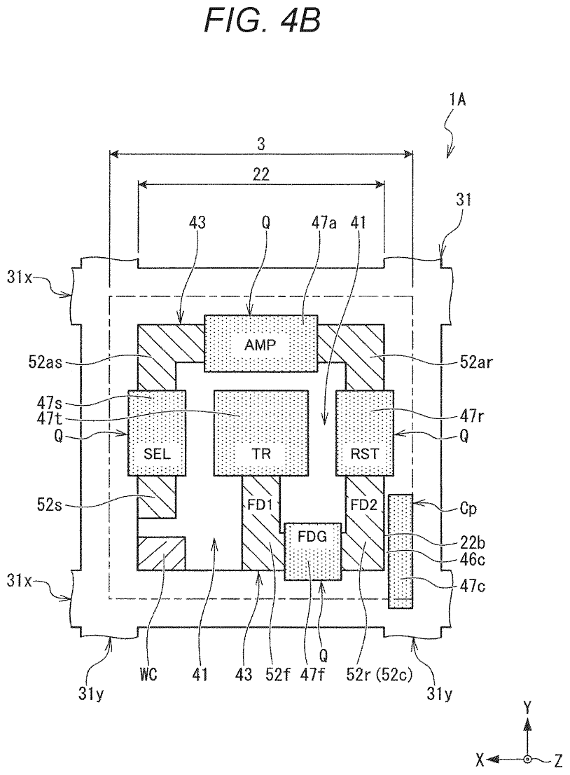

Next, a specific configuration of the semiconductor chip 2 (solid-state imaging device 1A) will be described with reference to FIGS. 4A to 6B.

In FIG. 4A, illustration of a multilayer wiring layer 55 to be described later is omitted, and illustration of a layer above a first wiring layer 57 included in the multilayer wiring layer 55 is omitted in FIGS. 5A and 6A for easy viewing of the drawing. Furthermore, FIG. 1 depicts the light incident surface side of the semiconductor chip 2, but FIG. 4A is a plan view of the semiconductor chip 2 as viewed from the side opposite to the light incident surface side (multilayer wiring layer side). Furthermore, in FIG. 6A, illustration of a planarization film 61, an optical filter 63, and a microlens 64 illustrated in FIG. 5A is omitted.

As illustrated in FIG. 5A, the semiconductor chip 2 includes a semiconductor layer 21 having a first surface portion S1 and a second surface portion S2 located on opposite sides in a thickness direction that is one direction (Z direction), an inter-pixel isolation region 31 as an isolation region extending in the thickness direction (Z direction) of the semiconductor layer 21, and a photoelectric conversion region 22 partitioned by the inter-pixel isolation region 31 and provided in the semiconductor layer 21.

In addition, as illustrated in FIG. 5A, the semiconductor chip 2 further includes the multilayer wiring layer 55 provided on the first surface portion S1 side of the semiconductor layer 21.

In addition, the semiconductor chip 2 further includes a planarization film 61, an optical filter 63, and a microlens (on-chip lens) 64 sequentially provided on the second surface portion S2 side of the semiconductor layer 21 from the second surface portion S2 side.

Here, the first surface portion S1 of the semiconductor layer 21 will also be referred to as a main surface or an element formation surface, and the second surface portion S2 will also be referred to as a back surface. Then, in the solid-state imaging device 1A according to the first embodiment, incident light incident from the second surface portion S2 side of the semiconductor layer 21 is photoelectrically converted by the photoelectric conversion unit 25 (photodiode PD) provided in the photoelectric conversion region 22 of the semiconductor layer 21. In the first embodiment, therefore, the second surface portion S2 of the semiconductor layer 21 will also be referred to as a light incident surface.

Furthermore, in the first embodiment, the inter-pixel isolation region 31 corresponds to a specific example of the “isolation region” of the present technology.

### <Planarization Film, Optical Filter, and Microlens>

The planarization film 61 illustrated in FIG. 5A is provided on the second surface portion S2 side of the semiconductor layer 21 so as to cover the second surface portion S2 of the semiconductor layer 21, and planarizes the second surface portion S2 side of the semiconductor layer 21.

The optical filter 63 and the microlens 64 illustrated in FIG. 5A are provided for each pixel 3 (photoelectric conversion region 22). The optical filter 63 color-isolates incident light incident from the light incident surface side (second surface portion S2 side) of the semiconductor chip 2. The microlens 64 condenses the irradiation light and allows the condensed light to efficiently enter the pixel 3 (photoelectric conversion region 22).

### <Semiconductor Layer>

As illustrated in FIG. 5A, the semiconductor layer 21 includes an inter-pixel isolation region 31 extending in the thickness direction (Z direction) of the semiconductor layer 21, and a photoelectric conversion region 22 partitioned by the inter-pixel isolation region 31. The photoelectric conversion region 22 is provided for each pixel 3. As the semiconductor layer 21, a Si substrate, a SiGe substrate, an InGaAs substrate, or the like may be used. In the first embodiment, although not limited to this, a p-type semiconductor substrate including, for example, single crystal silicon is used as the semiconductor layer 21.

### <Inter-Pixel Isolation Region>

### (Planar Shape)

As illustrated in FIG. 4A, the inter-pixel isolation region 31 includes a first planar portion 31x extending in the X direction and a second planar portion 31y extending in the Y direction in plan view. Then, the inter-pixel isolation region 31 further includes intersections (intersection points) where the first planar portion 31x and the second planar portion 31y intersect each other on the same plane. In the first embodiment, the first planar portion 31x and the second planar portion 31y are, for example, orthogonal to each other.

The first planar portions 31x are repeatedly arranged at predetermined intervals in the Y direction. Furthermore, the second planar portions 31y are repeatedly arranged at predetermined intervals in the X direction. That is, in the inter-pixel isolation region 31, a planar pattern in plan view is a lattice-shaped planar pattern.

As illustrated in FIG. 4A, the inter-pixel isolation region 31 corresponding to one photoelectric conversion region 22 is an annular planar pattern (ring-shaped planar pattern) having a square planar shape in plan view, and surrounds the periphery of one photoelectric conversion region 22. Then, the inter-pixel isolation region 31 corresponding to the pixel array unit 2A in which the plurality of pixels 3 is arranged is a composite planar pattern having a lattice-shaped planar pattern in a square annular planar pattern.

### (Cross-Sectional Shape)

As illustrated in FIG. 5A, the inter-pixel isolation region 31 extends in the thickness direction (Z direction) of the semiconductor layer 21, and electrically and optically isolates two photoelectric conversion regions 22 adjacent to each other in plan view. Then, the inter-pixel isolation region 31 is, for example, a dug type, a so-called trench type, in which a dug portion 33 is formed in the semiconductor layer 21 to partition and isolate the photoelectric conversion region 22.

The inter-pixel isolation region 31 includes, but is not limited to, for example, the dug portion 33 extending over the first surface portion S1 and the second surface portion S2 of the semiconductor layer 21, and an isolation insulating film 34 provided in the dug portion 33. That is, the inter-pixel isolation region 31 extends over the first surface portion S1 and the second surface portion S2 of the semiconductor layer 21. As the isolation insulating film 34, for example, a silicon oxide film may be used. In the first embodiment, the dug portion 33 is embedded in, for example, the isolation insulating film 34.

### <Photoelectric Conversion Region>

As illustrated in FIGS. 4A and 4B, the photoelectric conversion region 22 is surrounded by the inter-pixel isolation region 31 in plan view, and has a square planar shape. Specifically, the photoelectric conversion region 22 is surrounded by two first planar portions 31x extending in the X direction and separated in the Y direction and two second planar portions 31y extending in the Y direction and separated in the X direction in the inter-pixel isolation region 31. Then, the photoelectric conversion region 22 is partitioned by the first planar portion 31x and the second planar portion 31y, and is isolated from the other photoelectric conversion regions 22.

As illustrated in FIGS. 5A to 6B, the photoelectric conversion region 22 includes an upper surface portion 22a located on the first surface portion S1 side of the semiconductor layer 21 and a side surface portion (outer wall surface portion) 22b located on the inter-pixel isolation region 31 side.

Furthermore, the photoelectric conversion region 22 further includes the photoelectric conversion unit 25, the transfer transistor TR, the floating diffusion regions FD1 and FD2, and the capacitive element Cp described above.

Furthermore, as illustrated in FIGS. 4A to 6B, the photoelectric conversion region 22 further includes an inter-element isolation region (field isolation region) 41 provided on the upper surface portion 22a side, and an island-shaped element formation region (active region) 43 partitioned by the inter-element isolation region 41 and the inter-pixel isolation region 31 and provided on the upper surface portion 22a side (the first surface portion S1 side of the semiconductor layer 21).

Furthermore, the photoelectric conversion region 22 further includes an amplification transistor AMP, a selection transistor SEL, a reset transistor RST, and a switching transistor FDG as the pixel transistor Q included in the readout circuit 16 described above.

Furthermore, the photoelectric conversion region 22 further includes a p-type semiconductor region (well region) 23, an n-type semiconductor region 24, and a p-type power supply contact region WC (see FIGS. 4A and 4B).

(p-type Semiconductor Region and n-type Semiconductor Region)

As illustrated in FIGS. 5A and 5B, the p-type semiconductor region 23 is provided over a wide range over the first surface portion S1 side and the second surface portion S2 side of the semiconductor layer 21 in the photoelectric conversion region 22. Then, the p-type semiconductor region 23 is in contact with the inter-pixel isolation region 31 along the depth direction (Z direction) of the semiconductor layer 21.

As illustrated in FIGS. 5A and 5B, the n-type semiconductor region 24 is provided in the p-type semiconductor region 23 in the photoelectric conversion region 22. That is, in the n-type semiconductor region 24, six surfaces including an upper surface portion, a lower surface portion, and four side surface portions are surrounded by the p-type semiconductor region 23. Then, the n-type semiconductor region 24 is separated from the first surface portion S1 and the second surface portion S2 of the semiconductor layer 21 and the inter-pixel isolation region 31.

(photoelectric Conversion Unit)

The photoelectric conversion unit 25 illustrated in FIGS. 5A and 5B includes the p-type semiconductor region 23 and the n-type semiconductor region 24 in the photoelectric conversion region 22. Then, the photoelectric conversion unit 25 is configured as a pn junction type photodiode (PD) including a pn junction between the p-type semiconductor region 23 and the n-type semiconductor region 24.

The photoelectric conversion unit 25 photoelectrically converts light incident on the n-type semiconductor region 24 from the second surface portion S2 side of the semiconductor layer 21 into signal charges in the n-type semiconductor region 24, and temporarily holds (accumulates) the photoelectrically converted signal charges in the pn junction between the p-type semiconductor region 23 and the n-type semiconductor region 24.

### (Inter-element Isolation Region and Element Formation Region)

As illustrated in FIGS. 5A to 6B, the inter-element isolation region 41 is provided in a surface layer portion of the photoelectric conversion region 22 on the upper surface portion 22a side, that is, a surface layer portion of the semiconductor layer 21 on the first surface portion S1 side. The inter-element isolation region 41 has, but is not limited to, a shallow trench isolation (STI) structure in which an isolation insulating film 42b is embedded in a shallow groove portion 42a recessed from the first surface portion S1 toward the second surface portion S2 of the semiconductor layer 21, for example.

As illustrated in FIG. 4B, the inter-element isolation region 41 is an island-shaped planar pattern separated from the inter-pixel isolation region 31 except for a part in plan view, and partitions the element formation region 43 together with the inter-pixel isolation region 31.

As illustrated in FIGS. 5A to 6B, the element formation region 43 is provided in the surface layer portion of the photoelectric conversion region 22 on the upper surface portion 22a side, that is, the surface layer portion of the semiconductor layer 21 on the first surface portion S1 side.

Then, as illustrated in FIG. 4B, the element formation region 43 is partitioned by the inter-element isolation region 41 and the inter-pixel isolation region 31, and is a planar pattern extending in a ribbon shape along four sides of the photoelectric conversion region 22 in plan view. The planar pattern of the element formation region 43 is not limited thereto, but is the same in each pixel 3 (each photoelectric conversion region 22), for example.

(p-Type Power Supply Contact Region)

As illustrated in FIGS. 4B and 6B, the p-type power supply contact region WC is provided on a corner side sandwiched between two sides of the photoelectric conversion region 22 in plan view. The p-type power supply contact region WC is provided in the surface layer portion of the photoelectric conversion region 22 on the upper surface portion 22a side, that is, the surface layer portion of the semiconductor layer 21 on the first surface portion S1 side. Then, the p-type power supply contact region WC is provided in an island-shaped power supply region partitioned by the inter-element isolation region 41 and the inter-pixel isolation region 31 on the upper surface portion 22a side of the photoelectric conversion region 22. The p-type power supply contact region WC includes a p-type semiconductor region having a higher impurity concentration than the p-type semiconductor region 23. Then, the p-type power supply contact region WC is connected to the p-type semiconductor region 23 and electrically conducted.

A first reference potential of, for example, 0 V is applied to the p-type power supply contact region WC as a reference potential in the semiconductor chip 2 (in the solid-state imaging device 1A) during operation, and the potential is fixed to the first reference potential.

### (Floating Diffusion Region)

As illustrated in FIGS. 4A, 6A, and 6B, each of the floating diffusion regions FD1 and FD2 included in the charge holding unit 26 described above is provided in the p-type semiconductor region 23 in the element formation region 43 on the upper surface portion 22a side of the photoelectric conversion region 22, and forms a pn junction with the p-type semiconductor region 23. The floating diffusion regions FD1 and FD2 are shared with main electrode regions 52f and 52r of the switching transistor FDG to be described later, and are constituted by n-type semiconductor regions. Furthermore, the floating diffusion region FD2 is shared with a second electrode 52c of the capacitive element Cp included in the charge holding unit 26.

(transfer Transistor)

As illustrated in FIGS. 4B and 5B, the transfer transistor TR is provided on the first surface portion S1 side of the semiconductor layer 21, that is, on the upper surface portion 22a side of the photoelectric conversion region 22. The transfer transistor TR includes a gate electrode 47t provided over the inside and outside of the photoelectric conversion region 22 on the upper surface portion 22a side of the photoelectric conversion region 22, and a gate insulating film 46 provided between the gate electrode 47t and the semiconductor layer 21. Furthermore, the transfer transistor TR further includes an n-type semiconductor region 24 functioning as a source region, an n-type floating diffusion region FD1 functioning as a drain region, and a p-type semiconductor region 23 functioning as a channel formation portion. The transfer transistor TR is not limited thereto, but is configured as, for example, a vertical type.

As illustrated in FIG. 5B, the gate electrode 47t of the transfer transistor TR includes a head portion 47t₁ provided outside the first surface portion S1 of the semiconductor layer 21 with the gate insulating film 46 interposed therebetween, and a leg portion 47r₂ protruding from the head portion 47t₁ into the semiconductor layer 21 and adjacent to the semiconductor layer 21 with the gate insulating film 46 interposed therebetween. The gate electrode 47t of the first embodiment is not limited thereto, but is formed in, for example, a T-shaped longitudinal sectional shape in which the width of the leg portion 47t₂ is narrower than the width of the head portion 47t₁.

The leg portion 47t2 of the gate electrode 47t is provided in the dug portion of the semiconductor layer 21 with the gate insulating film 46 interposed therebetween, and enters the inside of the n-type semiconductor region 24 in a state where the distal end is insulated and isolated.

<pixel Transistors>

As illustrated in FIGS. 4B and 5B, the element formation region 43 is provided with a plurality of pixel transistors Q (AMP, SEL, RST, FDG) included in the readout circuit 16. Then, each of the plurality of pixel transistors Q is, for example, a planar type.

### (Reset Transistor)

As illustrated in FIGS. 4B and 5B, the reset transistor RST includes a gate electrode 47r provided on the upper surface portion 22a side of the photoelectric conversion region 22 (the first surface portion S1 side of the semiconductor layer 21) so as to overlap the element formation region 43 (semiconductor layer 21) in plan view, and a gate insulating film 46 interposed between the gate electrode 47r and the element formation region 43. Further, the reset transistor RST further includes a pair of main electrode regions 52r and 52ar provided in the element formation regions 43 on both sides of the gate electrode 47r in the gate length direction and functioning as a source region and a drain region. Furthermore, the reset transistor RST further includes a channel formation portion 53r provided in the element formation region 43 overlapping the gate electrode 47r in plan view. The pair of main electrode regions 52r and 52ar is separated from each other via the channel formation portion 53r. The pair of main electrode regions 52r and 52ar includes an n-type semiconductor region provided in the element formation region 43, and the channel formation portion 53r includes a p-type semiconductor region 23 provided in the element formation region 43.

(selection Transistor)

As illustrated in FIGS. 4B and 5B, the selection transistor SEL includes a gate electrode 47s provided on the upper surface portion 22a side of the photoelectric conversion region 22 (the first surface portion S1 side of the semiconductor layer 21) so as to overlap the element formation region 43 (semiconductor layer 21) in plan view, and a gate insulating film 46 interposed between the gate electrode 47s and the element formation region 43. In addition, the selection transistor SEL further includes a pair of main electrode regions 52s and 52as provided in the element formation regions 43 of the gate electrode 47s on both sides in the gate length direction and functioning as a source region and a drain region. In addition, the selection transistor SEL further includes a channel formation portion 53s provided in the element formation region 43 overlapping the gate electrode 47s in plan view. The pair of main electrode regions 52s and 52as is separated from each other via the channel formation portion 53s. The pair of main electrode regions 52s and 52as includes an n-type semiconductor region provided in the element formation region 43, and the channel formation portion 53s includes a p-type semiconductor region 23 provided in the element formation region 43.

(amplification Transistor)

Although not illustrated in detail, the amplification transistor AMP has a configuration similar to that of the reset transistor RST and the selection transistor SEL. That is, referring to FIGS. 4B and 5B, the amplification transistor AMP includes a gate electrode 47a provided on the upper surface portion 22a side of the photoelectric conversion region 22 (the first surface portion S1 side of the semiconductor layer 21) so as to overlap the element formation region 43 (semiconductor layer 21) in plan view, and a gate insulating film interposed between the gate electrode 47a and the element formation region 43. Further, the amplification transistor AMP further includes a pair of main electrode regions 52as and 52ar provided in the element formation regions 43 on both sides of the gate electrode 47a in the gate length direction and functioning as a source region and a drain region. Further, the amplification transistor AMP further includes a channel formation portion provided in the element formation region 43 overlapping the gate electrode 47a in plan view. The pair of main electrode regions 52as and 52ar is separated from each other via the channel formation portion. The pair of main electrode regions 52as and 52ar includes an n-type semiconductor region provided in the element formation region 43, and the channel formation portion includes a p-type semiconductor region 23 provided in the element formation region 43.

(switching Transistor)

As illustrated in FIGS. 4B and 6B, the switching transistor FDG includes a gate electrode 47f provided on the upper surface portion 22a side of the photoelectric conversion region 22 (the first surface portion S1 side of the semiconductor layer 21) so as to overlap the element formation region 43 (semiconductor layer 21) in plan view, and a gate insulating film 46 interposed between the gate electrode 47f and the element formation region 43. Furthermore, the switching transistor FDG further includes a pair of main electrode regions 52f and 52r provided in the element formation regions 43 of the gate electrode 47f on both sides in the gate length direction and functioning as a source region and a drain region. Furthermore, the switching transistor FDG further includes a channel formation portion 53f provided in the element formation region 43 overlapping the gate electrode 47f in plan view. The pair of main electrode regions 52f and 52r is separated from each other via the channel formation portion 53f. The pair of main electrode regions 52f and 52r includes an n-type semiconductor region provided in the element formation region 43, and the channel formation portion 53f includes a p-type semiconductor region 23 provided in the element formation region 43.

(sharing of Main Electrode Region)

As illustrated in FIG. 4B, the amplification transistor AMP and the selection transistor SEL share the main electrode region 52as of the amplification transistor AMP and the main electrode region 52as of the selection transistor SEL, and are provided in the element formation region 43 in series connection.

In addition, as illustrated in FIG. 4B, the amplification transistor AMP and the reset transistor SRT share the main electrode region 52ar of the amplification transistor AMP and the main electrode region 52ar of the reset transistor RST, and are provided in the element formation region 43 in series connection.

As illustrated in FIG. 4B, the switching transistor FDG and the transfer transistor TR share the main electrode region 52f of the switching transistor FDG and the main electrode region 52f of the transfer transistor TR, and are provided in the element formation region 43 in series connection. Then, the main electrode region 52f of each of the switching transistor FDG and the transfer transistor TR is shared with the floating diffusion region FD1.

### Furthermore, As Illustrated in Fig. 4b, the Switching

transistor FDG and the reset transistor RST share the main electrode region 52r of the switching transistor FDG and the main electrode region 52r of the reset transistor RST, and are provided in the element formation region 43 in series connection. Then, the main electrode region 52r of each of the switching transistor FDG and the reset transistor RST is shared with the floating diffusion region FD2.

### (Materials of Gate Insulating Film and Gate Electrode)

The gate insulating film 46 of each of the amplification transistor AMP, the selection transistor SEL, the reset transistor RST, the switching transistor FDG, and the transfer transistor TR includes, for example, a silicon oxide (SiO₂) film. Then, each of the gate electrodes 47a, 47s, 47r, 47f, and 47t of the transistors AMP, SEL, RST, FDG, and TR includes, for example, a polycrystalline silicon film (doped polysilicon film) into which an impurity for reducing the resistance value is introduced.

(enhancement Type)

Each of the pixel transistors Q (AMP, SEL, RST, FDG) included in the readout circuit 16 can be configured as, for example, an enhancement type (normally off type) in which a drain current flows by applying a gate voltage equal to or higher than a threshold voltage to the gate electrodes 47a, 47s, 47r, and 47f. Furthermore, each of the pixel transistors Q (AMP, SEL, RST, FDG) included in the readout circuit 16 can be configured as, for example, a depression type (normally on type) in which a drain current flows without applying a voltage to the gate electrodes 47a, 47s, 47r, and 47f. In the first embodiment, each of the reset transistor RST and the selection transistor SEL is of, but not limited to, an enhancement type. In the case of the enhancement type, in each of the pixel transistors Q (AMP, SEL, RST, FDG), a channel (inversion layer) electrically connecting the pair of main electrode regions is formed (induced) in the channel formation portion by a voltage applied to the gate electrodes 47a, 47s, 47r, and 47f, and a current (drain current) flows from the drain region side to the source region side through the channel of the channel formation portion.

Note that, similarly to the pixel transistor Q, the transfer transistor TR is also of an enhancement type, for example.

<capacitive Element Cp>

As illustrated in FIGS. 4B, 6A, and 6B, the capacitive element Cp includes a dielectric film 46c provided on the side surface portion 22b of the photoelectric conversion region 22, a first electrode 47c provided in the inter-pixel isolation region 31 adjacent to (facing) the side surface portion 22b of the photoelectric conversion region 22 with the dielectric film 46c interposed therebetween, and a second electrode 52c provided inside the side surface portion 22b of the photoelectric conversion region 22 adjacent to the first electrode 47c. The dielectric film 46c includes, for example, a silicon oxide film.

As illustrated in FIG. 6B, the first electrode 47c is not limited thereto, but for example, a part thereof is provided inside the inter-pixel isolation region 31, and the other part is provided outside the inter-pixel isolation region 31. That is, the first electrode 47c of the first embodiment is provided over the inside and outside of the inter-pixel isolation region 31 in the thickness direction (Z direction) of the semiconductor layer 21.

The first electrode 47c includes, for example, a polycrystalline silicon film (doped polysilicon film) into which an impurity for reducing the resistance value is introduced. The first electrode 47c can be formed in the same step as the gate electrode 47f of the switching transistor FDG.

The second electrode 52c includes a semiconductor region provided in the element formation region 43. The second electrode 52c of the first embodiment is shared with the main electrode region 52r of each of the switching transistor FDG and the reset transistor RST, and is shared with the floating diffusion region FD2. That is, the capacitive element Cp has a MOS structure.

As illustrated in FIG. 6B, the floating diffusion region FD2 is provided over the upper surface portion 22a and the side surface portion 22b of the photoelectric conversion region 22. Specifically, the floating diffusion region FD2 includes a first portion 52c₁ provided on the upper surface portion 22a of the photoelectric conversion region 22, and a second portion 52c₂ extending from the first portion 52c₁ along the side surface portion 22b of the photoelectric conversion region 22 to the side opposite to the first surface portion S1 of the semiconductor layer 21. That is, the second electrode 52c has an L-shaped vertical cross-sectional shape along the thickness direction (Z direction) of the semiconductor layer 21.

As illustrated in FIG. 4A, in the two photoelectric conversion regions 22(22Xa, 22Xb) arranged in the Y direction in plan view, the first electrode 47c of the capacitive element Cp in one photoelectric conversion region 22Xa is electrically connected to the main electrode region 52ar of the amplification transistor AMP and the reset transistor RST in the other photoelectric conversion region 22Xb via the wiring 58z. Although not illustrated, the wiring 58z is electrically connected to the above-described power supply line VDD.

### Multilayer Wiring Layer

As illustrated in FIGS. 5A to 6B, the multilayer wiring layer 55 is provided on the first surface portion S1 side of the semiconductor layer 21. Then, the multilayer wiring layer 55 includes an interlayer insulating film 56 provided on the first surface portion S1 side of the semiconductor layer 21 so as to cover the inter-element isolation region 41 and the element formation region 43, contact electrodes 57c, 57f, 57r, 57s, 57t, and 57w provided in the film of the interlayer insulating film 56, and a first wiring layer 58 provided on the side of the interlayer insulating film 56 opposite to the semiconductor layer 21 side. The first wiring layer 58 includes wirings 58c, 58r, 58s, 58t, and 58w. As a material of the contact electrodes 57c, 57f, 57r, 57s, 57t, and 57w, for example, tungsten (W) of a high melting point metal can be used. As a material of the first wiring layer 58, for example, a metal material such as aluminum (Al) or copper (Cu), an alloy material mainly containing Al or Cu, or the like can be used. As the interlayer insulating film 56, for example, a silicon oxide film can be used. The gate electrode 47t of the transfer transistor TR and the gate electrode (47a, 47s, 47r, 47f) of each of the plurality of pixel transistors Q (AMP, SEL, RST, FDG) are covered with the interlayer insulating film 56.

### <Contact Electrode and Wiring>

As illustrated in FIG. 5B, the gate electrode 47t of the transfer transistor TR is electrically connected to the wiring 58t provided in the wiring layer 58 on the interlayer insulating film 56 via the contact electrode 57t provided in the interlayer insulating film 56.

As illustrated in FIG. 5B, the gate electrode 47r of the reset transistor RST is electrically connected to the wiring 58r provided in the wiring layer 58 on the interlayer insulating film 56 via the contact electrode 57r provided in the interlayer insulating film 56.

As illustrated in FIG. 5B, the gate electrode 47s of the selection transistor SEL is electrically connected to the wiring 58s provided in the wiring layer 58 on the interlayer insulating film 56 via the contact electrode 57s provided in the interlayer insulating film 56.

As illustrated in FIG. 6B, the gate electrode 47f of the switching transistor FDG is electrically connected to the wiring 58f provided in the wiring layer 58 on the interlayer insulating film 56 via the contact electrode 57f provided in the interlayer insulating film 56.

As illustrated in FIG. 6B, the first electrode 47c of the capacitive element Cp is electrically connected to the wiring 58c provided in the wiring layer 58 on the interlayer insulating film 56 via the contact electrode 57c provided in the interlayer insulating film 56.

Note that, although not illustrated, the gate electrode 47a of the amplification transistor AMP is electrically connected to the wiring provided in the wiring layer 58 on the interlayer insulating film 56 via a contact electrode provided in the interlayer insulating film 56.

### Method for Manufacturing Solid-State Imaging Device

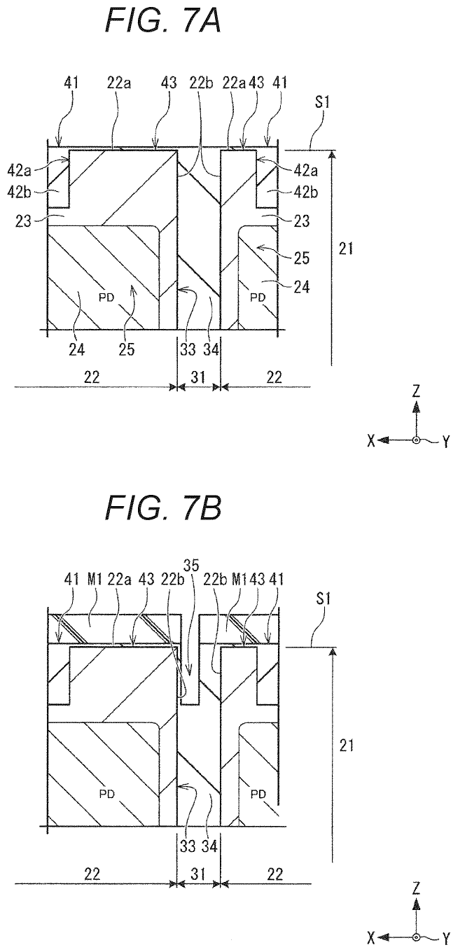

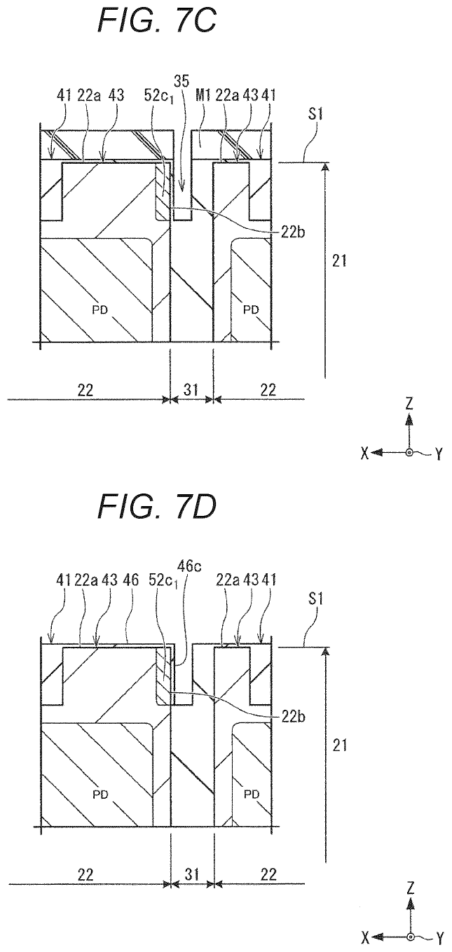

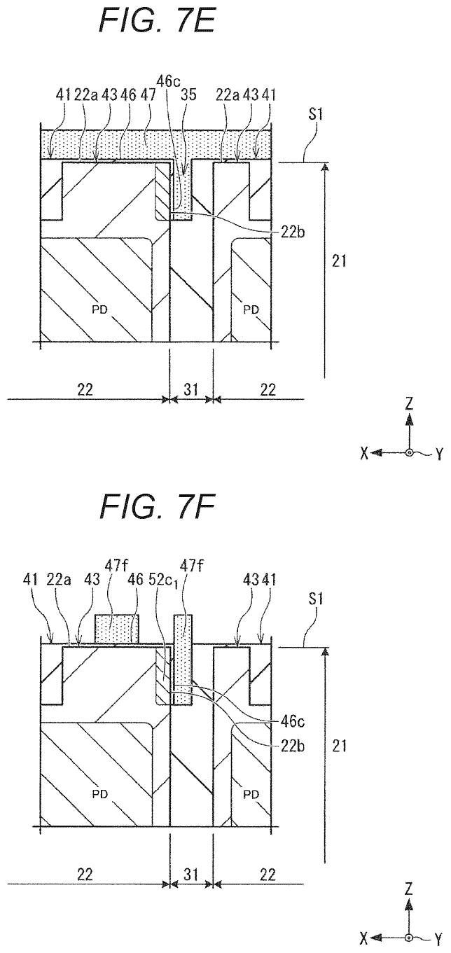

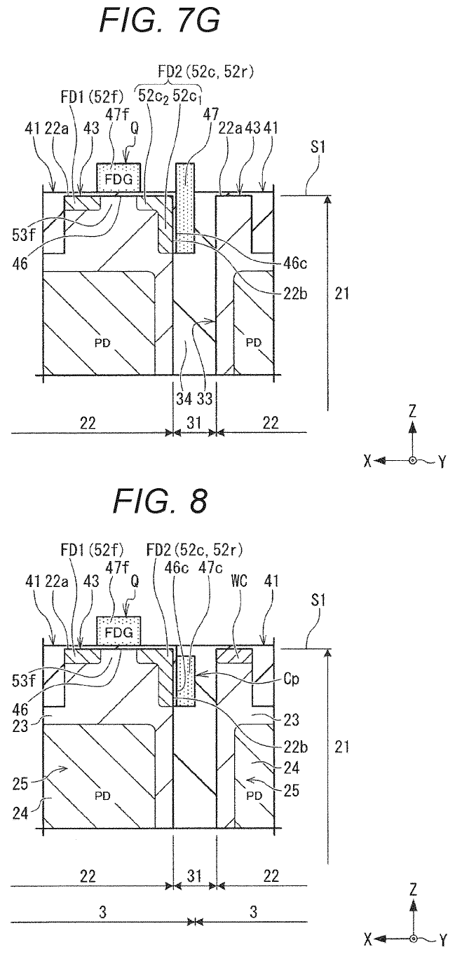

Next, a method of manufacturing the solid-state imaging device 1A according to the first embodiment of the present technology will be described with reference to FIGS. 7A to 7H.

In the first embodiment, manufacturing of the capacitive element Cp included in the method for manufacturing the solid-state imaging device 1A will be specifically described.

First, as illustrated in FIG. 7A, the photoelectric conversion region 22, the p-type semiconductor region 23, the n-type semiconductor region 24, the photoelectric conversion unit 25, the inter-pixel isolation region 31, the inter-element isolation region 41, the element formation region 43, and the like are formed in the semiconductor layer 21.

The inter-pixel isolation region 31 can be formed by forming the dug portion 33 extending in the thickness direction (Z direction) of the semiconductor layer 21 in the semiconductor layer 21, and then selectively embedding the dug portion 33 with the isolation insulating film 34.

The inter-element isolation region 41 can be formed by forming the shallow groove portion 42a on the first surface portion S1 side of the semiconductor layer 21 and then selectively embedding the shallow groove portion 42a with the isolation insulating film 42b.

Then, by forming the inter-pixel isolation region 31 and the inter-element isolation region 41, the photoelectric conversion region 22 partitioned by the inter-pixel isolation region 31 and the inter-element isolation region 41 and having the upper surface portion 22a and the side surface portion 22b is formed. Further, the element formation region 43 partitioned by the inter-element isolation region 41 is formed on the upper surface portion 22a side of the photoelectric conversion region 22.

Next, as illustrated in FIG. 7B, a dug portion 35 extending in the thickness direction (Z direction) of the semiconductor layer 21 is formed in the inter-pixel isolation region 31 along the side surface portion 22b of the photoelectric conversion region 22. The dug portion 35 can be formed, for example, by forming a mask M1 on the first surface portion S1 of the semiconductor layer 21 by a known photolithography technique, and then selectively etching the inter-pixel isolation region 31 exposed from the opening of the mask M1 by an anisotropic dry etching technique.

Next, as illustrated in FIG. 7C, a first portion 52c₁ including an n-type semiconductor region extending along the side surface portion 22b from the upper surface portion 22a side of the photoelectric conversion region 22 to the side opposite to the upper surface portion 22a side is formed inside the side surface portion 22b of the photoelectric conversion region 22. The first portion 52c₁ can be formed, for example, by ion-implanting impurities into the side surface portion 22b of the photoelectric conversion region 22 through the opening of the mask M1 and the dug portion 35, and then performing heat treatment for activating the ion-implanted impurities.

Next, the mask M1 is selectively removed, and a natural oxide film and an excessive insulating film of the upper surface portion 22a and the side surface portion 22b of the photoelectric conversion region 22 on the first surface portion S1 side of the semiconductor layer 21 are removed by, for example, wet etching to expose the semiconductor layer 21 on the upper surface portion 22a and the side surface portion 22b of the photoelectric conversion region 22.

Next, after the semiconductor layer 21 on the upper surface portion 22a and the side surface portion 22b of the photoelectric conversion region 22 is exposed, as illustrated in FIG. 7D, the gate insulating film 46 is formed on the semiconductor layer 21 on the upper surface portion 22a of the photoelectric conversion region 22, and the dielectric film 46c adjacent to the first portion 52c₁ is formed on the semiconductor layer 21 on the side surface portion 22b of the photoelectric conversion region 22.

As the gate insulating film 46 and the dielectric film 46c, for example, a silicon oxide film can be used. The silicon oxide film can be formed by a thermal oxidation method or a deposition method, but in the first embodiment, the silicon oxide film by the thermal oxidation method is formed as the gate insulating film 46 and the dielectric film 46c. The thermal oxidation method can form a silicon oxide film having better film quality than the deposition method.

In this step, the dielectric film 46c and the gate insulating film 46 are formed in the same step.

Next, as illustrated in FIG. 7E, a conductive film 47 is formed. The conductive film 47 is formed on the first surface portion S1 side of the semiconductor layer 21 so as to embed the inside of the dug portion 35. As the conductive film 47, a polycrystalline silicon film that can be formed by a CVD method can be used.

Next, the conductive film 47 is patterned to form the gate electrode 47f and the first electrode 47c as illustrated in FIG. 7F. Although the gate electrode 47f of the switching transistor FDG is illustrated in FIG. 7F, the gate electrodes of the amplification transistor AMP, the selection transistor SEL, the reset transistor RST, and the transfer transistor TR are also formed in this step.

In this step, the first electrode 47c is formed in a shape that is adjacent to each of the side surface portion 22b and the first portion 52c₁ of the photoelectric conversion region 22 with the dielectric film 46c interposed therebetween and extends across the inside and outside of the inter-pixel isolation region 31 in the thickness direction (Z direction) of the semiconductor layer 21.

Furthermore, in this step, each of the gate electrode 47f and the other gate electrodes is formed in the element formation region 43 of the photoelectric conversion region 22 with the gate insulating film 46 interposed therebetween.

Furthermore, in this step, the first electrode 47c and the gate electrode of the pixel transistor Q are formed in the same step.

Next, as illustrated in FIG. 7G, the second portion 52c₂ including the n-type semiconductor region is formed on the upper surface portion 22a of the element formation region 43 of the photoelectric conversion region 22, and the floating diffusion region FD1 including the n-type semiconductor region is formed. Each of the second portion 52c₂ and the floating diffusion region FD1 can be formed, for example, by selectively ion-implanting impurities into the element formation region 43 of the photoelectric conversion region 22 and then performing heat treatment for activating the ion-implanted impurities.

In this step, the floating diffusion region FD2 including the first portion 52c₁ and the second portion 52c₂ is formed, and the second electrode 52c shared with the floating diffusion region FD2 is formed.

In addition, in this step, the capacitive element Cp including the first electrode 47c, the dielectric film 46c, and the second electrode 52c and electrically connected to the floating diffusion region FD2 is formed.

Furthermore, in this step, the main electrode region 52f shared with the floating diffusion region FD1 is formed, and the main electrode region 52r shared with the floating diffusion region FD2 is formed.

Furthermore, in this step, the channel formation portion 53r is formed in the element formation region 43 overlapping the gate electrode 47f in plan view and sandwiched between the main electrode region 52f and the main electrode region 52r.

Furthermore, in this step, the switching transistor FDG including the gate insulating film 46, the gate electrode 47f, the pair of main electrode regions 52f and 52r, and the channel formation portion 53f is formed as the pixel transistor Q.

Note that, although not illustrated, in this step, as the other pixel transistors Q, the amplification transistor AMP, the selection transistor SEL, and the reset transistor RST are also formed in the element formation region 43 of the photoelectric conversion region 22, and the transfer transistor TR is also formed in the element formation region 43 of the photoelectric conversion region 22.

### Main Effects of First Embodiment

Next, main effects of the first embodiment will be described.

As illustrated in FIG. 3, the solid-state imaging device 1A according to the first embodiment includes a capacitive element Cp connected to the floating diffusion region FD2. Then, as illustrated in FIGS. 4B and 6B, the capacitive element Cp includes a first electrode 47c provided in the inter-pixel isolation region 31 adjacent to the side surface portion 22b of the photoelectric conversion region 22 with the dielectric film 46c interposed therebetween, and a second electrode 52c provided inside the side surface portion 22b of the photoelectric conversion region 22 adjacent to the first electrode 47c.

Therefore, as compared with a case where each of the first electrode 47c and the second electrode 52c of the capacitive element Cp is arranged in the photoelectric conversion region 22, the area occupied by the capacitive element Cp in the photoelectric conversion region 22 can be reduced, and the degree of freedom in arrangement (degree of freedom in layout) of arranging elements such as the capacitive element Cp, the pixel transistor Q (AMP, RST, SEL, FDG), and the transfer transistor TR in the photoelectric conversion region 22 can be increased. Therefore, according to the solid-state imaging device 1A according to the first embodiment, it is possible to increase the degree of freedom in arrangement of elements in the photoelectric conversion region 22.

In addition, since the area occupied by the capacitive element Cp in the photoelectric conversion region 22 can be reduced, the photoelectric conversion region 22 can be miniaturized without miniaturizing the pixel transistor Q (AMP, SEL, RST, FDG) and the transfer transistor TR provided in the photoelectric conversion region 22. As a result, it is possible to achieve miniaturization of the photoelectric conversion region 22, that is, miniaturization of the pixel 3 while suppressing characteristic deterioration accompanying miniaturization of the pixel transistor Q (AMP, SEL, RST, FDG) and the transfer transistor TR provided in the photoelectric conversion region 22.

In addition, each of the first electrode 47c and the second electrode 52c of the capacitive element Cp is provided adjacent to each other at the side surface portion 22b of the photoelectric conversion region 22 with the dielectric film 46c interposed therebetween. Therefore, the area of each of the first electrode 47c and the second electrode 52c can be expanded in the thickness direction (Z direction) of the semiconductor layer 21, and the capacitance can be increased without expanding the planar size of the capacitive element Cp.

Furthermore, the second electrode 52c of the capacitive element Cp is shared with the floating diffusion region FD2.

Therefore, the planar size of the photoelectric conversion region 22 can be reduced, and the number of pixels of the pixel array unit 2A can be increased without increasing the planar size of the pixel array unit 2A. In recent years, an image sensor capable of high resolution has been demanded in the market, and can contribute to high resolution of the image sensor.

In addition, since the second electrode 52c of the capacitive element Cp is shared with the floating diffusion region FD2, the wiring electrically connecting the second electrode 52c and the floating diffusion region FD2 can be omitted, and the wiring density of the multilayer wiring layer 55 overlapping the photoelectric conversion region 22 in plan view can be reduced. As a result, the degree of freedom in routing the wiring connected to the pixel transistor Q (AMP, SEL, RST, FDG) of the photoelectric conversion region 22 can be increased, and the restriction on the arrangement of the pixel transistor Q due to the routing of the wiring can be relaxed.

Here, normally, in the image sensor, in order to expand the dynamic range and improve the low illuminance characteristics, a transistor (switching transistor FDG) for switching the conversion efficiency is provided, and driving is often performed with high conversion efficiency at the low illuminance and low conversion efficiency at the high illuminance.

In the high illuminance region, since the charge holding unit 26 receives signal charges (transferred charges) from the photoelectric conversion unit 25, the diffusion capacitance in the floating diffusion regions FD1 and FD2 is small, and a capacitance is often added. Therefore, in order to increase the capacitance, a wiring capacitance, a MOS capacitance, a MIM capacitance, or the like may be connected.

Since the dynamic range performance is determined by the FD capacitance in the charge holding unit 26, the FD capacitance is preferably as large as possible particularly when overflow drive (LOFIC) is performed.

The wiring capacitance cannot be made so large from the viewpoint of reliability, and forming the MIM portion in the photoelectric conversion region 22 has disadvantages in terms of cost and structure, so that MOS capacitance has been often used.

However, in the conventional MOS capacitance, since an electrode is formed on a Si surface with an insulating film interposed therebetween, it is necessary to increase the area when increasing the capacitance. Therefore, it is necessary to reduce the size of the pixel transistor Q, and reducing the size of the pixel transistor Q affects characteristics such as deterioration in variation in transistor characteristics and random noise.

On the other hand, since the capacitive element Cp of the present technology can increase the capacitance without expanding the planar size, it is useful for expanding the dynamic range and improving the low illuminance characteristics without affecting the characteristics such as the deterioration in the variation in the transistor characteristics and the random noise.

### Modifications of First Embodiment

### <Modification 1-1>

In the first embodiment described above, the case where the first electrode 47c of the capacitive element Cp is provided across the inside and outside of the inter-pixel isolation region 31 in the thickness direction (Z direction) of the semiconductor layer 21 has been described, but the present technology is not limited to the first embodiment described above.

For example, as illustrated in FIG. 8, the first electrode 47c may be embedded in the inter-pixel isolation region 31. Also in Modification 1-1, effects similar to those of the first embodiment described above can be obtained.

### <Modification 1-2>

Furthermore, in the first embodiment described above, a case where a silicon oxide film is used as the dielectric film 46c of the capacitive element Cp has been described, but the present technology is not limited to the first embodiment described above.

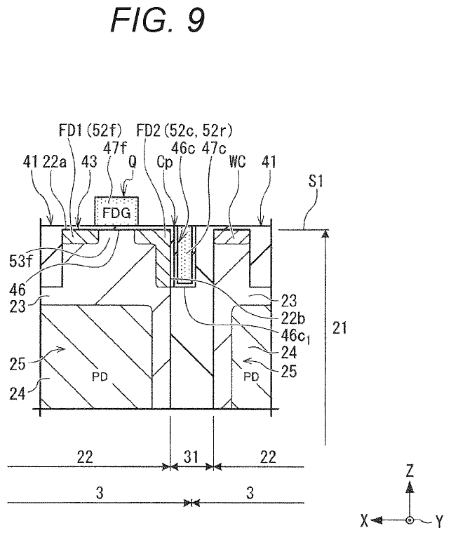

For example, as illustrated in FIG. 9, the dielectric film 46c of the capacitive element Cp may include a film 46c₁ having a dielectric constant higher than that of the isolation insulating film of the inter-pixel isolation region. Also in Modification 1-2, effects similar to those of the first embodiment described above can be obtained. In addition, in Modification 1-2, the capacity can be increased with the same size as compared with the first embodiment described above.

### Second Embodiment

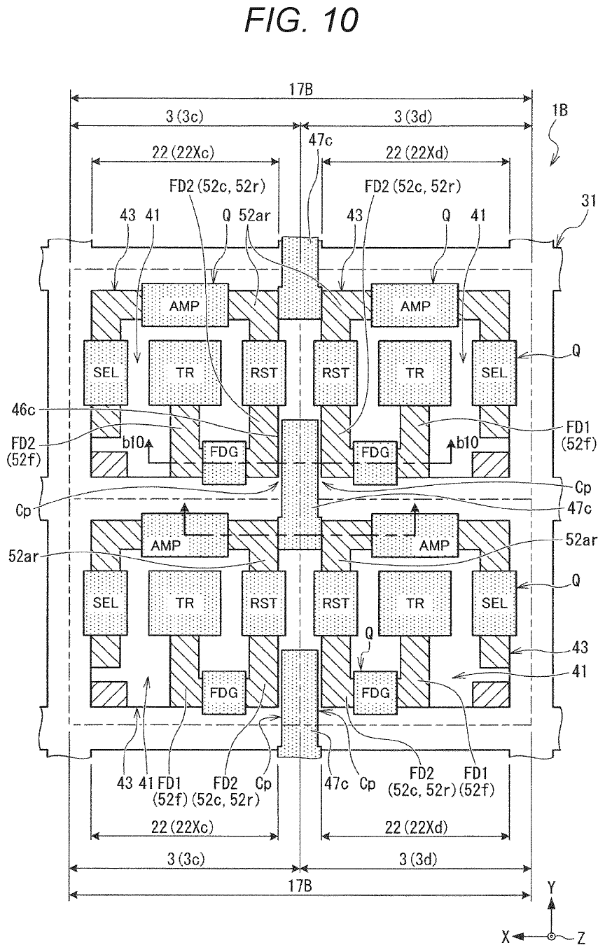

Next, a solid-state imaging device 1B according to a second embodiment of the present technology will be described with reference to FIGS. 10 to 12.

FIG. 10 is a plan view schematically illustrating a configuration example of two pixel blocks in the solid-state imaging device according to the second embodiment of the present technology.

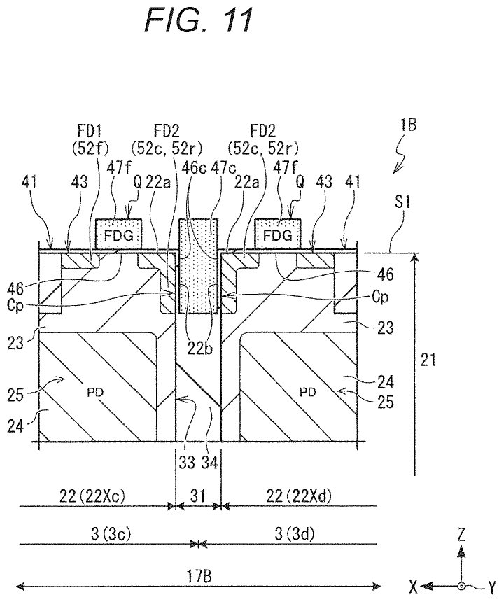

FIG. 11 is a longitudinal sectional view schematically illustrating a longitudinal sectional structure taken along line a10-a10 in FIG. 10.

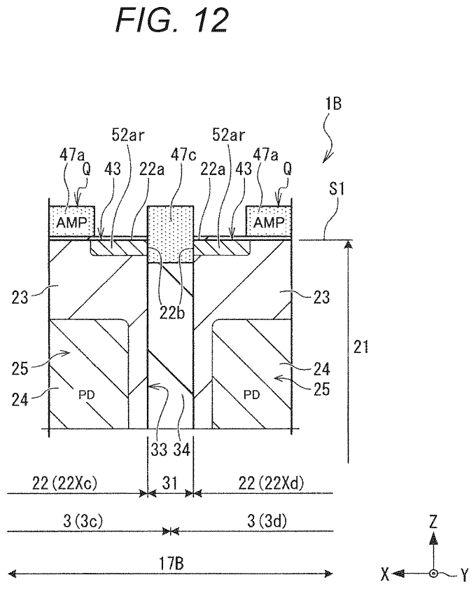

FIG. 12 is a longitudinal sectional view schematically illustrating a longitudinal sectional structure taken along line b10-b10 in FIG. 10.

The solid-state imaging device 1B according to the second embodiment of the present technology includes a pixel block 17B illustrated in FIG. 10. The pixel block 17B of the second embodiment includes two pixels 3 (3c, 3d) adjacent to each other in the X direction in plan view as one unit. FIG. 10 illustrates two pixel blocks 17B arranged in the Y direction in plan view.

As illustrated in FIG. 10, each of two pixels 3 (3c, 3d) included in one pixel block 17B includes a photoelectric conversion region 22 (22Xc, 22Xd) partitioned by an inter-pixel isolation region 31. The photoelectric conversion region 22 (22Xc, 22Xd) of the second embodiment basically has a configuration similar to that of the photoelectric conversion region 22 of the first embodiment described above, and the following configuration is different.

That is, in the pixel block 17B of the second embodiment, in the photoelectric conversion region 22(22Xc, 22Xd) of each of the two pixels 3 (3c, 3d), the planar pattern of the element formation region 43 in one photoelectric conversion region 22Xc and the planar pattern of the element formation region 43 in the other photoelectric conversion region 22Xd are inverted around the boundary between the pixel 3c and the pixel 3d arranged in the X direction.

Then, in the photoelectric conversion region 22(22Xc, 22Xd) of each of the two pixels 3 (3 c, 3d), the capacitive element Cp of one photoelectric conversion region 22Xc and the capacitive element Cp of the other photoelectric conversion region 22Xd share the first electrode 47c.

Specifically, as illustrated in FIG. 11, the first electrode 47c is shared by two photoelectric conversion regions 22 (22Xc, 22Xd) adjacent to each other with the inter-pixel isolation region 31 interposed therebetween in plan view, and is adjacent to (facing) each other with the second electrode 52c (floating diffusion region FD2) and the dielectric film 46c interposed therebetween in each side surface portion 22b of the two photoelectric conversion regions 22(22Xc, 22Xd).

Furthermore, as illustrated in FIG. 10, in the two pixel blocks 17B arranged in the Y direction in plan view, the first electrode 47c of one pixel block 17B is extended to the other pixel block 17B across the inter-pixel isolation region 31. Then, as illustrated in FIG. 12, the first electrode 47c of one pixel block 17B is electrically and mechanically connected to the main electrode region 52ar of each of the amplification transistors AMP provided in each of the two photoelectric conversion regions 22 (22Xc, 22Xd) in the side surface portion 22b of each of the two photoelectric conversion regions 22(22Xc, 22Xd) included in the other pixel block 17B. Then, although not illustrated, the power supply wiring line VDD is electrically connected to the first electrode 47c.

The solid-state imaging device 1B according to the second embodiment can also produce effects similar to the effects produced by the solid-state imaging device 1A according to the first embodiment described above.

Furthermore, in the second embodiment, in the photoelectric conversion region 22 (22Xc, 22Xd) of each of the two pixels 3 (3c, 3d) included in one pixel block 17B, the capacitive element Cp of one photoelectric conversion region 22Xc and the capacitive element Cp of the other photoelectric conversion region 22Xd share the first electrode 47c. Therefore, the contact electrode and the wiring connected to the first electrode 47c can also be shared, and the wiring density of the multilayer wiring layer 55 overlapping the pixel block 17B in plan view can be reduced. As a result, the degree of freedom in routing the wiring connected to the pixel transistor Q of the photoelectric conversion region 22 can be increased, and the restriction on the arrangement of the pixel transistor Q due to the routing of the wiring can be relaxed. Therefore, according to the solid-state imaging device 1B according to the second embodiment, the degree of freedom in arrangement of the pixel transistors Q in the photoelectric conversion region 22 can be further increased as compared with the solid-state imaging device 1A according to the first embodiment described above.

Furthermore, in the second embodiment, in the two pixel blocks 17B arranged in the Y direction in plan view, the first electrode 47c of one pixel block 17B is extended to the other pixel block 17B across the inter-pixel isolation region 31. Then, the first electrode 47c of one pixel block 17B is electrically and mechanically connected to the main electrode region 52ar of each of the amplification transistors AMP provided in each of the two photoelectric conversion regions 22 (22Xc, 22Xd) in the side surface portion 22b of each of the two photoelectric conversion regions 22(22Xc, 22Xd) included in the other pixel block 17B. Then, the power supply wiring VDD is electrically connected to the first electrode 47c. As a result, the contact electrode and the wiring connected to the main electrode region 52ar of the amplification transistor AMP can also be shared with the contact electrode and the wiring connected to the first electrode 47c, so that the degree of freedom of arrangement of the pixel transistors Q in the photoelectric conversion region 22 can be further increased as compared with the solid-state imaging device 1A according to the first embodiment described above.

Note that, in the second embodiment, the capacitive element Cp sharing the first electrode 47c is described as two capacitive elements Cp, but two capacitive elements Cp sharing the first electrode 47c can also be regarded as one capacitive element Cp.

### Third Embodiment

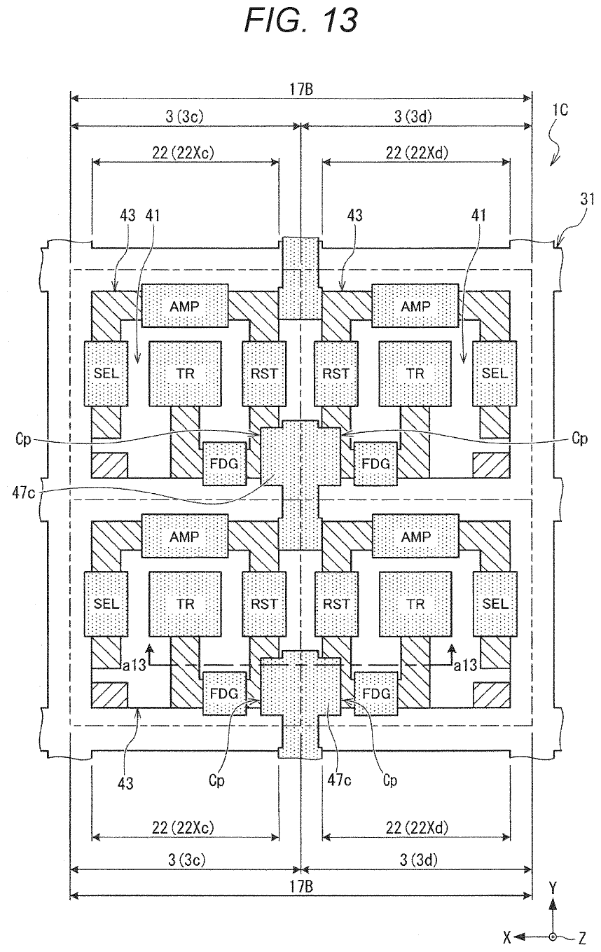

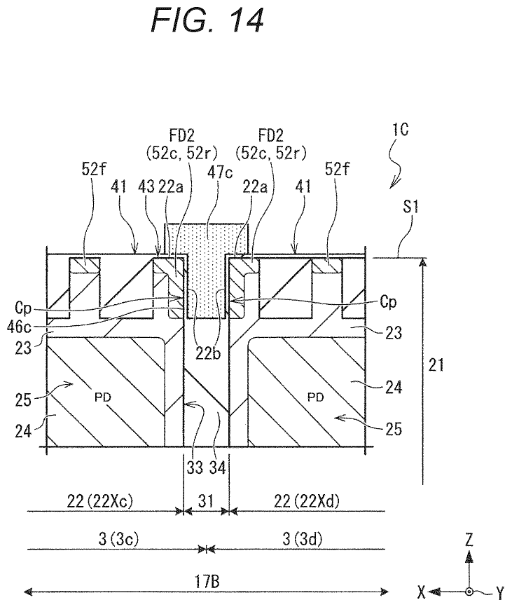

Next, a solid-state imaging device 1C according to a third embodiment of the present technology will be described with reference to FIGS. 13 and 14.

FIG. 13 is a plan view schematically illustrating a configuration example of two pixel blocks in the solid-state imaging device according to the third embodiment of the present technology.

FIG. 14 is a longitudinal sectional view schematically illustrating a longitudinal sectional structure taken along line a13-a13 in FIG. 13.

As illustrated in FIGS. 13 and 14, the solid-state imaging device 1C according to the third embodiment of the present technology basically has a configuration similar to that of the solid-state imaging device 1B according to the second embodiment described above, and the configuration of the first electrode 47c of the capacitive element Cp is different.

That is, as illustrated in FIGS. 13 and 14, the first electrode 47c of the third embodiment is provided over the upper surface portion 22a and the side surface portion 22b of the photoelectric conversion region 22 with the dielectric film 46c interposed therebetween.

In the third embodiment, the second electrode 52c (floating diffusion region FD2) is provided over the upper surface portion 22a and the side surface portion 22b of the photoelectric conversion region 22. Therefore, the first electrode 47c of the third embodiment is adjacent to (faces) the second electrode 52c across the upper surface portion 22a and the side surface portion 22b of the photoelectric conversion region 22 with the dielectric film 46c interposed therebetween.

Furthermore, in the third embodiment, the first electrode 47c is shared by the capacitive elements Cp of the two photoelectric conversion regions 22 arranged in the X direction in plan view. Therefore, the first electrode 47c of the third embodiment is provided over the upper surface portion 22a and the side surface portion 22b of each of the two photoelectric conversion regions 22 arranged in the X direction in plan view, and is adjacent to the second electrode 52c of each of the two photoelectric conversion regions 22 with the dielectric film 46c interposed therebetween.

The first electrode 47c of the third embodiment extends over the photoelectric conversion region 22 and the inter-pixel isolation region 31 in plan view outside the first surface portion S1 of the semiconductor layer 21, and has a head portion in which the dielectric film 46c is interposed in the upper surface portion 22a of the photoelectric conversion region 22 and a leg portion protruding from the head portion toward the inter-pixel isolation region 31 and adjacent to the second electrode 52c (floating diffusion region FD2) with the dielectric film 46c interposed therebetween in the side surface portion 22b of the photoelectric conversion region 22.

Also in the solid-state imaging device 1C according to the third embodiment, effects similar to those of the solid-state imaging device 1B according to the second embodiment described above can be obtained.

In addition, in the capacitive element Cp of the third embodiment, since each of the first electrode 47c and the second electrode 52c is provided over the upper surface portion 22a and the side surface portion 22b of the photoelectric conversion region 22, the capacitance can be increased as compared with the capacitive element Cp of the first and second embodiments described above.

Note that the configuration in which the first electrode 47c of the capacitive element Cp is provided over the upper surface portion 22a and the side surface portion 22b of the photoelectric conversion region 22 can also be applied to the capacitive element Cp of the first embodiment described above.

### Modifications of Third Embodiment

### <Modification 3-1>

In the third embodiment described above, the case where the first electrode 47c of the capacitive element Cp is provided over the upper surface portion 22a and the side surface portion 22b of the photoelectric conversion region 22 with the dielectric film 46c interposed therebetween has been described, but the present technology is not limited to the first embodiment described above.

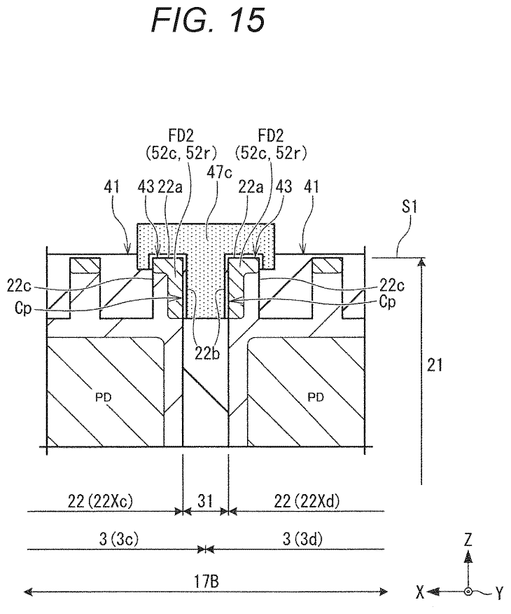

For example, as illustrated in FIG. 15, the first electrode 47c of the capacitive element Cp may be provided over each of the upper surface portion 22a and the two side surface portions 22b and 22c of the photoelectric conversion region 22 with the dielectric film 46c interposed therebetween. In the case of Modification 3-1, the second electrode 52c (floating diffusion region FD2) is also provided over each of the upper surface portion 22a and the two side surface portions 22b and 22c of the photoelectric conversion region 22. Then, the first electrode 47c of the capacitive element Cp is adjacent to the second electrode 52c (floating diffusion region FD2) across each of the upper surface portion 22a and the two side surface portions 22b and 22c of the photoelectric conversion region 22 with the dielectric film 46c interposed therebetween. The side surface portion (inner side surface portion) 22c of the photoelectric conversion region 22 is located on the side opposite to the side surface portion (outer side surface portion) 22b of the photoelectric conversion region 22 in plan view, and is adjacent to the inter-element isolation region 41.

Also in this Modification 3-1, effects similar to those of the third embodiment described above can be obtained.

In addition, in the capacitive element Cp of Modification 3-1, since each of the first electrode 47c and the second electrode 52c is provided over each of the upper surface portion 22a and the two side surface portions 22b and 22c of the photoelectric conversion region 22, the capacitance can be increased as compared with the capacitive element Cp of the third embodiment described above.

### Fourth Embodiment

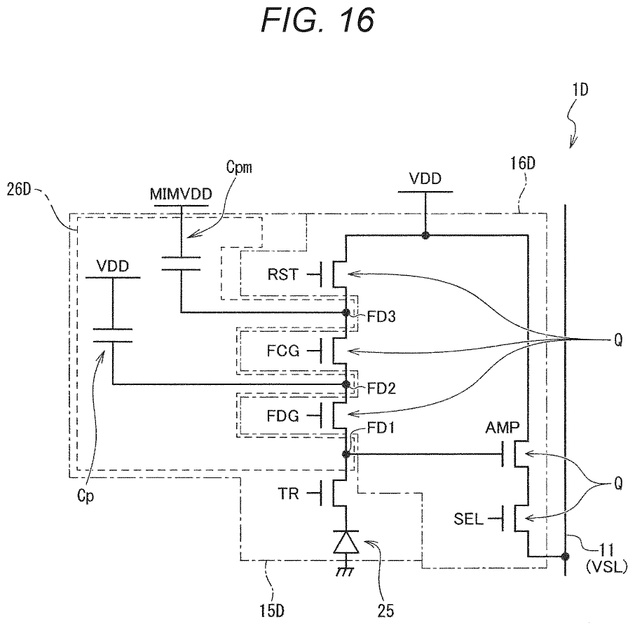

Next, a solid-state imaging device 1D according to a fourth embodiment of the present technology will be described with reference to FIGS. 16 to 18.

FIG. 16 is an equivalent circuit diagram illustrating a configuration example of a readout circuit in the solid-state imaging device according to the fourth embodiment of the present technology.

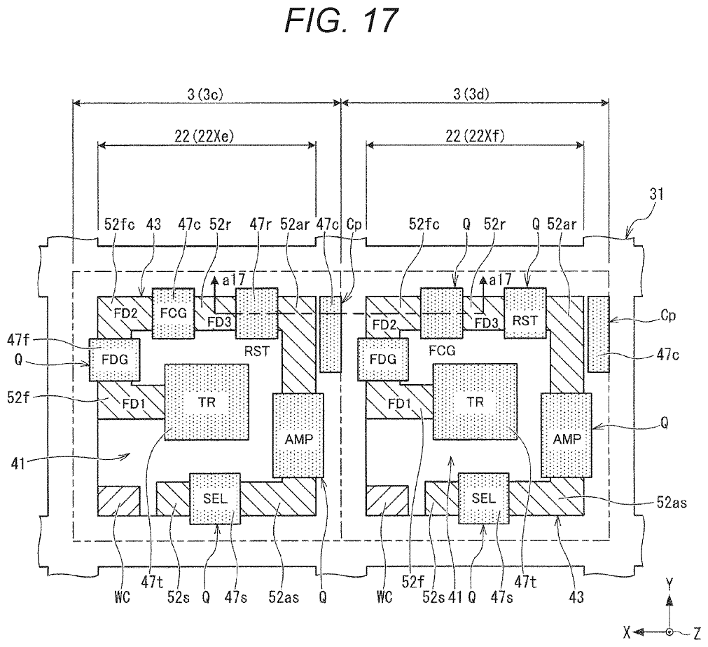

FIG. 17 is a plan view schematically illustrating a configuration example of two pixels in the solid-state imaging device according to the fourth embodiment of the present technology.

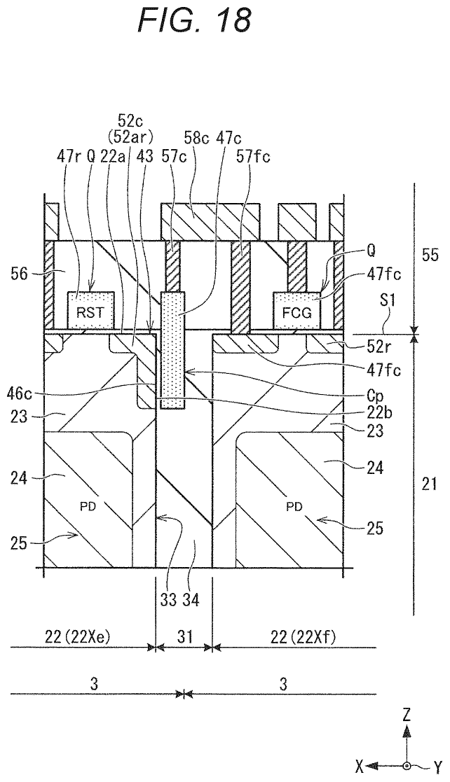

FIG. 18 is a longitudinal sectional view schematically illustrating a longitudinal sectional structure taken along line a17-a17 in FIG. 17.

As illustrated in FIGS. 16 to 18, the solid-state imaging device 1D according to the fourth embodiment of the present technology basically has a configuration similar to that of the solid-state imaging device 1A according to the first embodiment described above, and differs in the following configuration.

That is, the solid-state imaging device 1D of the fourth embodiment includes a photoelectric conversion circuit 15D and a readout circuit 16D illustrated in FIG. 16 instead of the photoelectric conversion circuit 15 and the readout circuit 16 illustrated in FIG. 3 of the first embodiment described above.

Then, in the fourth embodiment, the transistor layout of the photoelectric conversion region 22 is slightly different from that of the first embodiment described above.. Other configurations are substantially similar to those in the first embodiment.

### <Photoelectric Conversion Circuit and Readout Circuit>

As illustrated in FIG. 16, the photoelectric conversion circuit 15D includes, but is not limited to, a photoelectric conversion unit 25, a charge holding unit 26 that holds (accumulates) the signal charge photoelectrically converted by the photoelectric conversion unit 25, and a transfer transistor TR that transfers the signal charge photoelectrically converted by the photoelectric conversion unit 25 to the charge holding unit 26D, for example. The photoelectric conversion circuit 15D is provided for each pixel 3.

The readout circuit 16D includes, but is not limited to, an amplification transistor AMP, a selection transistor SEL, a reset transistor RST, and two switching transistors FCG and FDG as the pixel transistor Q, for example. That is, the readout circuit 16D of the fourth embodiment has a five-transistor configuration.

Here, in the fourth embodiment, as an example, a circuit configuration in which one readout circuit 16D is allocated to each pixel 3 is adopted, but the present invention is not limited to the fourth embodiment. For example, a circuit configuration may be adopted in which one readout circuit 16D is allocated to two pixels 3 as one unit, or a circuit configuration may be adopted in which one readout circuit 16D is allocated to three or more pixels 3 as one unit.

<photoelectric Conversion Circuit>

### (Photoelectric Conversion Unit and Transfer Transistor)

Since the photoelectric conversion unit 25 and the transfer transistor TR illustrated in FIG. 16 have configurations similar to those of the photoelectric conversion unit 25 and the transfer transistor TR of the first embodiment described above, the description of the fourth embodiment will be omitted.

### (Charge Holding Unit)

Unlike the charge holding unit 26 of the first embodiment described above, the charge holding unit 26D includes three floating diffusion regions FD1, FD2, and FD3, and a capacitive element Cp having a MOS structure and a capacitive element Cpm having a metal insulator metal (MIM) structure as capacitive elements.

Similarly to the first embodiment described above, the floating diffusion region FD1 is connected between the transfer transistor TR and the switching transistor FDG. The floating diffusion region FD2 is connected between the switching transistors FDG and FCG. The floating diffusion region FD3 is connected between the switching transistor FCG and the reset transistor RST.

The capacitive element Cp is connected to the floating diffusion region FD2, similarly to the first embodiment described above. The capacitive element Cpm is connected to the floating diffusion region FD3.

The floating diffusion region FD1 temporarily accumulates and holds the signal charge transferred from the photoelectric conversion unit 25 via the transfer transistor TR.

The floating diffusion region FD2 and the capacitive element Cp temporarily accumulate and hold the signal charge transferred from the photoelectric conversion unit 25 via the transfer transistor TR when the switching transistor FDG is in a conductive state (ON state).

The floating diffusion region FD3 and the capacitive element Cpm temporarily store and hold the signal charge transferred from the photoelectric conversion unit 25 via the transfer transistor TR when each of the switching transistors FDG and FCG is in a conductive state (ON state).

### <Readout Circuit>

As illustrated in FIG. 16, an input stage of the readout circuit 16D is electrically connected to the floating diffusion region FD1 of the charge holding unit 26D. Then, when the switching transistor FDG is in a non-conductive state (OFF state), the readout circuit 16D reads out the signal charges held in the floating diffusion region FD1 of the charge holding unit 26. Furthermore, when the switching transistor FDG is in a conductive state (ON state) and the switching transistor FCG is in a non-conductive state (OFF state), the readout circuit 16D reads out the signal charges held in the floating diffusion regions FD1 and FD2 of the charge holding unit 26 and the capacitive element Cp. Furthermore, when each of the switching transistors FDG and FCG is in a conductive state (ON state), the readout circuit 16D reads out the signal charges held in the floating diffusion regions FD1, FD2, and FD3 of the charge holding unit 26 and the capacitive elements Cp and Cpm.

Then, the readout circuit 16D outputs a pixel signal based on the read signal charge. In other words, the readout circuit 16D converts the signal charge photoelectrically converted by the photoelectric conversion unit 25 (photodiode PD) into a pixel signal based on the signal charge and outputs the pixel signal.

The pixel transistor Q (AMP, RST, SEL, FCG, FDG) included in the readout circuit 16D and the transfer transistor TR included in the photoelectric conversion circuit 15D are configured as insulated gate field effect transistors, for example, MOSFETs. Furthermore, the pixel transistor Q and the transfer transistor TR may be MISFETs.

Each of the amplification transistor AMP and the selection transistor SEL illustrated in FIG. 16 is connected in a manner similar to that in the first embodiment described above, and thus the description of the fourth embodiment is omitted.

In the reset transistor RST illustrated in FIG. 16, the source region is electrically connected to each of the floating diffusion region FD3 of the charge holding unit 26D and the drain region of the switching transistor FCG, and the drain region is electrically connected to each of the power supply line VDD and the drain region of the amplification transistor AMP. Then, a gate electrode of the reset transistor RST is electrically connected to a reset transistor drive line among the pixel drive lines 10 illustrated in FIG. 2.

In the switching transistor FCG illustrated in FIG. 16, the source region is electrically connected to each of the floating diffusion region FD2 of the charge holding unit 26D and the drain region of the switching transistor FDG, and the drain region is electrically connected to each of the floating diffusion region FD3 of the charge holding unit 26D and the drain region of the reset transistor RST. Then, the gate electrode of the switching transistor FCG is electrically connected to the second switching transistor drive line among the pixel drive lines 10 illustrated in FIG. 2.

In the switching transistor FDG illustrated in FIG. 16, the source region is electrically connected to each of the floating diffusion region FD1 of the charge holding unit 26D, the drain region of the transfer transistor TR, and the gate electrode of the amplification transistor AMP, and the drain region is electrically connected to each of the floating diffusion region FD2 of the charge holding unit 26 and the drain region of the switching transistor FCG. Then, the gate electrode of the switching transistor FDG is electrically connected to the first switching transistor drive line among the pixel drive lines 10 illustrated in FIG. 2.

When the transfer transistor TR is turned on, the transfer transistor TR illustrated in FIG. 16 transfers the signal charge generated by the photoelectric conversion unit 25 (photodiode PD) to the charge holding unit 26D.

When the reset transistor RST is turned on, the reset transistor RST illustrated in FIG. 16 resets the potential (signal charge) of the charge holding unit 26D(FD1, FD2, FD3, Cp, Cpm) to the potential of the power supply line VDD.

The selection transistor SEL illustrated in FIG. 16 controls the output timing of the pixel signal from the readout circuit 16.

The amplification transistor AMP illustrated in FIG. 16 generates a signal of a voltage corresponding to the level of the signal charge held in the charge holding unit 26D as a pixel signal. The amplification transistor AMP constitutes a source follower type amplifier, and outputs a pixel signal having a voltage corresponding to the level of the signal charge generated by the photoelectric conversion unit 25 (photodiode PD). When the selection transistor SEL is turned on, the amplification transistor AMP amplifies the potential of the charge holding unit 26D and outputs a voltage corresponding to the potential to the column signal processing circuit 5 via the vertical signal line 11 (VSL).

Similarly to the switching transistor FDG of the first embodiment described above, each of the two switching transistors FCG and FDG illustrated in FIG. 16 controls charge retention by the floating diffusion regions FD1, FD2, and FD3, and adjusts the multiplication factor of the voltage according to the potential amplified by the amplification transistor AMP. Then, by switching on/off of each of the two switching transistors FCG and FDG, the FD capacitance C can be made variable and the conversion efficiency can be switched, similarly to the readout circuit 16 of the first embodiment described above.

Although not illustrated in detail, referring to FIG. 17, the switching transistor FCG includes a gate electrode 47f provided in the element formation region 43 of the photoelectric conversion region 22 with a gate insulating film interposed therebetween, and a pair of main electrode regions 52fc and 52r provided in the element formation region 43 of the photoelectric conversion region 22 to be separated from each other in the gate length direction of the gate electrode 47f in plan view and functioning as a source region and a drain region. In addition, the switching transistor FCG further includes a channel formation portion provided in the element formation region 43 (semiconductor layer 21) overlapping the gate electrode 47f in plan view. The pair of main electrode regions 52f and 52r includes an n-type semiconductor region, and the channel formation portion includes a p-type semiconductor region 23.

Although not illustrated in detail, referring to FIG. 17, the switching transistor FDG includes a gate electrode 47f provided in the element formation region 43 of the photoelectric conversion region 22 with a gate insulating film interposed therebetween, and a pair of main electrode regions 52f and 52fc provided in the element formation region 43 of the photoelectric conversion region 22 to be separated from each other in the gate length direction of the gate electrode 47f in plan view and functioning as a source region and a drain region. Furthermore, the switching transistor FDG further includes a channel formation portion provided in the element formation region 43 (semiconductor layer 21) overlapping the gate electrode 47f in plan view. The pair of main electrode regions 52f and 52fc includes an n-type semiconductor region, and the channel formation portion includes a p-type semiconductor region 23.

In the fourth embodiment, the reset transistor RST and the switching transistor FCG are connected in series such that the main electrode region 52r of the reset transistor RST and the main electrode region 52r of the switching transistor FCG are shared. In addition, the switching transistor FCG and the switching transistor FDG share the main electrode region 52fc of the switching transistor FCG and the main electrode region 52fc of the switching transistor FDG, and are connected in series. That is, each of the reset transistors RST and the two switching transistors FCG and FDG is provided in the element formation region 43 of the photoelectric conversion region 22 in a state of being directly connected.

Furthermore, in the fourth embodiment, the floating diffusion region FD1 is shared with the main electrode region 52f of the switching transistor FDG. Furthermore, the floating diffusion region FD2 is shared with the main electrode region 52fc of the switching transistors FDG and FCG. Furthermore, the floating diffusion region FD3 is shared with the main electrode region 52r of the switching transistor FCDG and the reset transistor RST.

### <Capacitive Element Cp>

As illustrated in FIG. 18, the capacitive element Cp of the fourth embodiment includes a dielectric film 46c provided on the side surface portion 22b of the photoelectric conversion region 22, a first electrode 47c provided in the inter-pixel isolation region 31 adjacent to (facing) the side surface portion 22b of the photoelectric conversion region 22 with the dielectric film 46c interposed therebetween, and a second electrode 52c provided inside the side surface portion 22b of the photoelectric conversion region 22 adjacent to the first electrode 47c, similarly to the first embodiment described above.

The capacitive element Cp of the fourth embodiment is different from that of the first embodiment in the configuration of the second electrode 52c. That is, as illustrated in FIG. 6B, the second electrode 52c of the first embodiment described above is shared with the main electrode region 52r of the switching transistor FDG. On the other hand, as illustrated in FIG. 18, the capacitive element Cp of the fourth embodiment is shared with the recess transistor RST and the main electrode region 52ar of the amplification transistor AMP.

Then, as illustrated in FIG. 18, in the two photoelectric conversion regions 22 (22Xe, 22Xf) arranged adjacent to each other in the X direction in plan view, the first electrode 47c of the capacitive element Cp in which the second electrode 52c is provided in one photoelectric conversion region 22Xe is electrically connected to the wiring 58c provided in the wiring layer 58 on the interlayer insulating film 56 via the contact electrode 57c provided in the interlayer insulating film 56. Then, the wiring 58c is electrically connected to the main electrode region 47fc of the switching transistor FCG provided in the other photoelectric conversion region 22 via the contact electrode 57fc provided in the interlayer insulating film 56.

### <Capacitive Element Cpm>

Although not illustrated, the capacitive element Cpm having the MIM structure is provided in, for example, the multilayer wiring layer 55. The capacitive element Cpm having the MIM structure can be configured by two wiring layers and one interlayer insulating film in the multilayer wiring layer 55, and a large capacity can be achieved.

### Main Effects of Fourth Embodiment

The solid-state imaging device 1D according to the fourth embodiment can also produce effects similar to the effects produced by the solid-state imaging device 1A according to the first embodiment described above.

In addition, the fourth embodiment is effective in a case where the capacitive element Cpm having the MIM structure is connected to the floating diffusion region FD3, and a wiring capacitance or a high capacitance by the capacitive element Cpm having the MIM structure is not required in the floating diffusion region FD2.

### Fifth Embodiment

### Example of Application to Electronic Apparatus

The present technology (technology of the present disclosure) can be applied to various electronic apparatuses such as an imaging device such as a digital still camera or a digital video camera, a mobile phone having an imaging function, or other apparatuses having an imaging function, for example.

FIG. 19 is a diagram illustrating a schematic configuration of an electronic apparatus (for example, a camera) according to a fourth embodiment of the present technology.

As illustrated in FIG. 19, an electronic apparatus 100 includes a solid-state imaging device 101, an optical lens 102, a shutter device 103, a drive circuit 104, and a signal processing circuit 105. The electronic apparatus 100 illustrates an embodiment in a case where the solid-state imaging devices 1A to 1D according to the first to fourth embodiments of the present technology are used in an electronic apparatus (for example, a camera) as the solid-state imaging device 101.

The optical lens 102 forms an image of image light (incident light 106) from a subject on an imaging plane of the solid-state imaging device 101. Therefore, signal charge is accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (timing signal) supplied from the drive circuit 104, the solid-state imaging device 101 performs charge transfer. The signal processing circuit 105 performs various types of signal processing on a signal (pixel signal (image signal) output from the solid-state imaging device 101. A video signal obtained as a result of the signal processing is stored into a storage medium such as a memory, or is output to a monitor.

With such a configuration, in the solid-state imaging device 101, since the pixels 3 are miniaturized, the image quality performance of the electronic apparatus 100 of the eleventh embodiment can be improved.

Note that the electronic apparatus 100 to which the solid-state imaging devices according to the embodiments described above can be applied is not limited to a camera, and the solid-state imaging devices can also be applied to other electronic apparatuses. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. Also in this ranging sensor, the pixel transistor described above can be adopted.

Note that the present technology may have the following configurations.

(1)

A photodetection device including a semiconductor layer including a photoelectric conversion region that has a first surface portion and a second surface portion located opposite to each other in a thickness direction and is partitioned by an isolation region extending in the thickness direction, in which
the photoelectric conversion region includes:
an upper surface portion located on the first surface portion side of the semiconductor layer;
a side surface portion located on the isolation region side;
a pixel transistor provided on the upper surface portion side;
a floating diffusion region that is provided on the upper surface portion side and holds a signal charge photoelectrically converted by the photoelectric conversion unit; and
a capacitive element connected to the floating diffusion region, and
the capacitive element includes:
a first electrode provided in the isolation region adjacent to the side surface portion of the photoelectric conversion region with a dielectric film interposed therebetween; and
a second electrode provided adjacent to the first electrode inside the side surface portion of the photoelectric conversion region.
   (2)

The photodetection device according to (1), in which
the floating diffusion region is provided over the upper surface portion and the side surface portion of the photoelectric conversion region, and
the second electrode is shared with the floating diffusion region.
   (3)

The photodetection device according to (1) or (2), in which the first electrode is provided over an inside and an outside of the isolation region.

(4)

The photodetection device according to (1) or (2), in which the first electrode is embedded in the isolation region.

(5)

The photodetection device according to (1) or (2), in which the first electrode is provided along the upper surface portion and the side surface portion of the photoelectric conversion region with the dielectric film interposed therebetween.

(6)

The photodetection device according to any one of (1) to (5), in which the first electrode is shared by the two photoelectric conversion regions adjacent to each other with the isolation region interposed therebetween in plan view, and the first electrode is adjacent to the second electrode of each of the two photoelectric conversion regions with the dielectric film interposed therebetween.

(7)

The photodetection device according to any one of (1) to (5), in which in the two photoelectric conversion regions adjacent to each other with the isolation region interposed therebetween in plan view, the first electrode adjacent to the second electrode in one of the photoelectric conversion regions is connected to a main electrode region of the pixel transistor provided in the other photoelectric conversion region at the side surface portion of the other photoelectric conversion region.

(8)

The photodetection device according to any one of (1) to (7), in which
the isolation region includes a dug portion provided in the semiconductor layer and an isolation insulating film embedded in the dug portion, and
the dielectric film includes a film having a higher dielectric constant than the isolation insulating film.
   (9)

An electronic apparatus including:
an optical lens that forms an image of image light from a subject on an imaging surface of the photodetection device; and
a signal processing circuit that performs signal processing on a signal output from the photodetection device, the photodetection device including a semiconductor layer including a photoelectric conversion region that has a first surface portion and a second surface portion located opposite to each other in a thickness direction and is partitioned by an isolation region extending in the thickness direction, in which
the photoelectric conversion region includes:
an upper surface portion located on the first surface portion side of the semiconductor layer;
a side surface portion located on the isolation region side;
a pixel transistor provided on the upper surface portion side;
a floating diffusion region that is provided on the upper surface portion side and holds a signal charge photoelectrically converted by the photoelectric conversion unit; and
a capacitive element connected to the floating diffusion region, and
the capacitive element includes:
a first electrode provided in the isolation region adjacent to the side surface portion of the photoelectric conversion region with a dielectric film interposed therebetween; and
a second electrode provided adjacent to the first electrode inside the side surface portion of the photoelectric conversion region.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A, 1B, 1C, 1D Solid-state imaging device
2 Semiconductor chip
2A Pixel array unit
2B Peripheral portion
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Photoelectric conversion circuit
16 Readout circuit (pixel circuit)
21 Semiconductor layer
22 Photoelectric conversion region
22a Upper surface portion
22b Side surface portion
23 p-type semiconductor region
24 n-type semiconductor region
25 Photoelectric conversion unit
26 Charge holding unit
31 Inter-pixel isolation region (isolation region)
31b₁ First vertical portion
31b₂ Second vertical portion
31bz Step portion
31x First planar portion
31 y Second planar portion
31z₁ First vertical portion
31z₂ Second vertical portion
33 Dug portion
34 Isolation insulating film
41 Inter-element isolation region (field isolation region)
42a Shallow groove portion
42b Isolation insulating film
43 Element formation region (active region)
46 Gate insulating film
46c Dielectric film
47 Electrode film
47a, 47r, 47s, 47t Gate electrode
47t₁ Head portion
47t₂ Leg portion
47c First electrode
51 Dug portion
52as, 52as, 52r, 52s Main electrode region
52c Second electrode
52c₁ First portion
52c₂ Second portion
53f, 53r, 53s Channel formation portion
55 Multilayer wiring layer
56 Interlayer insulating film
57 First wiring layer
57a, 57f, 57r, 57s, 57t Contact electrode
58a, 58r, 58s, 58t Wiring
61 Planarization film
63 Optical filter
64 Microlens
100 Electronic apparatus
101 Solid-state imaging device
102 Optical lens (optical system)
103 Shutter device
104 Drive circuit
105 Signal processing circuit
AMP Amplification transistor
FD1, FD2 n-type floating diffusion region
FCG, FDG Switching transistor
Q Pixel transistor
RST Reset transistor
SEL Selection transistor
S1 First surface portion
S2 Second surface portion
TR Transfer transistor
WC Power supply contact region

1. A photodetection device comprising a semiconductor layer including a photoelectric conversion region that has a first surface portion and a second surface portion located opposite to each other in a thickness direction and is partitioned by an isolation region extending in the thickness direction, wherein
the photoelectric conversion region includes:
an upper surface portion located on the first surface portion side of the semiconductor layer;
a side surface portion located on the isolation region side;
a pixel transistor provided on the upper surface portion side;
a floating diffusion region that is provided on the upper surface portion side and holds a signal charge photoelectrically converted by the photoelectric conversion unit; and
a capacitive element connected to the floating diffusion region, and
the capacitive element includes:
a first electrode provided in the isolation region adjacent to the side surface portion of the photoelectric conversion region with a dielectric film interposed therebetween; and
a second electrode provided adjacent to the first electrode inside the side surface portion of the photoelectric conversion region.

2. The photodetection device according to claim 1, wherein
the floating diffusion region is provided over the upper surface portion and the side surface portion of the photoelectric conversion region, and
the second electrode is shared with the floating diffusion region.

3. The photodetection device according to claim 1, wherein the first electrode is provided over an inside and an outside of the isolation region.

4. The photodetection device according to claim 1, wherein the first electrode is embedded in the isolation region.

5. The photodetection device according to claim 1, wherein the first electrode is provided along the upper surface portion and the side surface portion of the photoelectric conversion region with the dielectric film interposed therebetween.

6. The photodetection device according to claim 1, wherein the first electrode is shared by the two photoelectric conversion regions adjacent to each other with the isolation region interposed therebetween in plan view, and the first electrode is adjacent to the second electrode of each of the two photoelectric conversion regions with the dielectric film interposed therebetween.

7. The photodetection device according to claim 1, wherein in the two photoelectric conversion regions adjacent to each other with the isolation region interposed therebetween in plan view, the first electrode adjacent to the second electrode in one of the photoelectric conversion regions is connected to a main electrode region of the pixel transistor provided in the other photoelectric conversion region at the side surface portion of the other photoelectric conversion region.

8. The photodetection device according to claim 1, wherein
the isolation region includes a dug portion provided in the semiconductor layer and an isolation insulating film embedded in the dug portion, and
the dielectric film includes a film having a higher dielectric constant than the isolation insulating film.

9. An electronic apparatus comprising:
a photodetection device;
an optical lens that forms an image of image light from a subject on an imaging surface of the photodetection device; and
a signal processing circuit that performs signal processing on a signal output from the photodetection device, the photodetection device including a semiconductor layer including a photoelectric conversion region that has a first surface portion and a second surface portion located opposite to each other in a thickness direction and is partitioned by an isolation region extending in the thickness direction, wherein
the photoelectric conversion region includes:
an upper surface portion located on the first surface portion side of the semiconductor layer;
a side surface portion located on the isolation region side;
a pixel transistor provided on the upper surface portion side;
a floating diffusion region that is provided on the upper surface portion side and holds a signal charge photoelectrically converted by the photoelectric conversion unit; and
a capacitive element connected to the floating diffusion region, and
the capacitive element includes:
a first electrode provided in the isolation region adjacent to the side surface portion of the photoelectric conversion region with a dielectric film interposed therebetween; and
a second electrode provided adjacent to the first electrode inside the side surface portion of the photoelectric conversion region.
